(19) United States
(12) Patent Application Publication
(10) Pub. No.: US 2006/0105106 A1
(43) Pub. Date: May 18, 2006

(54) Tensile and compressive stressed materials for semiconductors

(75) Inventors: Mihaela Balseanu, Sunnyvale, CA (US); Kee Bum Jung, Gilroy, CA (US); Lihua Li Huang, San Jose, CA (US); Li-Qun Xia, Santa Clara, CA (US); Rongping Wang, Cupertino, CA (US); Derek R. Witty, Fremont, CA (US); Lewis Stern, Williston, VT (US); Martin Jay Seamons, San Jose, CA (US); Hichem M'Saad, Santa Clara, CA (US); Michael Chiu Kwan, Sunnyvale, CA (US)

Correspondence Address: APPLIED MATERIALS, INC.;Patent Department, M/S 2061, P.O. Box 450A, Santa Clara, CA, 95052, US

(73) Assignee: Applied Materials, Inc.

(21) Appl. No.: 11/055,936

(22) Filed: Feb. 11, 2005

Related U.S. Application Data
(60) Provisional application No. 60/628,600, filed on Nov. 16, 2004.

(51) Int. Cl. C23C 16/00; B05D 3/00; H05H 1/24

(52) U.S. Cl. 427/248.1; 427/532; 427/569

(57) ABSTRACT

A stressed film is formed on a substrate. The substrate is placed in a process zone and a plasma is formed of a process gas provided in the process zone, the process gas having silicon-containing gas and nitrogen-containing gas. A diluent gas such as nitrogen can also be added. The as-deposited stressed material can be exposed to ultraviolet radiation or electron beams to increase the stress value of the deposited material. In addition or in the alternative, a nitrogen plasma treatment can be used to increase the stress value of the material during deposition. Pulsed plasma methods to deposit stressed materials are also described.

### CROSS-REFERENCE

This application claims priority from U.S. Provisional Application No. 60/628,600, filed on Nov. 16, 2004, entitled “DEPOSITION AND TREATMENT OF TENSILE AND COMPRESSIVE STRESSED LAYERS”, by Balseanu et al., which is incorporated herein by reference in its entirety.

### BACKGROUND

In the processing of a substrate to fabricate circuits and displays, the substrate is typically exposed to an energized process gas capable of depositing or etching material on the substrate. In chemical vapor deposition (CVD) processes, process gas energized by a high frequency voltage or microwave energy is used to deposit material on the substrate, which may be a layer, a filling of contact holes, or other selective deposition structures. The deposited layer can be etched or otherwise processed to form active and passive devices on the substrate, such as for example, metal-oxide-semiconductor field effect transistors (MOSFETs) and other devices. A MOSFET typically has a source region, a drain region, and a channel region between the source and drain. In the MOSFET device, a gate electrode is formed above and separated from the channel by a gate dielectric to control conduction between the source and drain.

The performance of such devices can be improved by, for example, reducing supply voltage, gate dielectric thickness, or channel length. However, such conventional methods face mounting problems as the size and spacing of the devices become ever smaller. For example, at very small channel lengths, the advantages of reducing channel length to increase the number of transistors per unit area and saturation current are offset by undesirable carrier velocity saturation effects. Similar benefits which are obtained from reducing gate dielectric thickness, such as decreased gate delay, are limited in small devices by increased gate leakage current and charge tunneling through the dielectric which can damage the transistor over time. Reducing supply voltage allows lower operating power levels but such reductions are also limited by the threshold voltage of the transistor.

In a relatively newly developed method of enhancing transistor performance, the atomic lattice of a deposited material is stressed to improve the electrical properties of the material itself, or of underlying or overlying material that is strained by the force applied by a stressed deposited material. Lattice strain can increase the carrier mobility of semiconductors, such as silicon, thereby increasing the saturation current of the doped silicon transistors to thereby improve their performance. For example, localized lattice strain can be induced in the channel region of the transistor by the deposition of component materials of the transistor which have internal compressive or tensile stresses. For example, silicon nitride materials used as etch stop materials and spacers for the silicide materials of a gate electrode can be deposited as stressed materials which induce a strain in the channel region of a transistor. The type of stress desirable in the deposited material depends upon the nature of the material being stressed. For example, in CMOS device fabrication, negative-channel (NMOS) doped regions are covered with a tensile stressed material having positive tensile stress; whereas positive channel MOS (PMOS) doped regions are covered with a compressive stressed material having negative stress values.

Thus, it is desirable to form stressed materials that have predetermined types of stresses, such as tensile or compressive stresses. It is further desirable to control the level of stress generated in the deposited material. It is also desirable to deposit such stressed materials to generate uniform localized stresses or strains in the substrate. It is also desirable to have a process that can form stressed materials over active or passive devices on the substrate without damaging the devices.

### SUMMARY

In one version, a stressed material is formed on a substrate. The substrate is placed in a process zone and a plasma is formed of a process gas provided in the process zone, the process gas having a silicon-containing gas and a nitrogen-containing gas. A diluent gas such as nitrogen can also be added. The as-deposited material is exposed to ultraviolet radiation or electron beams to increase the stress of the deposited silicon nitride material.

In another method of depositing a stressed material on a substrate, the substrate is placed in a process zone, and in a first process cycle, a plasma is maintained of a process gas provided into the process zone. The process gas has a first component having a silicon-containing gas and a nitrogen-containing gas that is not nitrogen, and a second component having nitrogen. Thereafter, in a second process cycle, the flow of the first component of the process gas is stopped while the plasma of the second component having nitrogen is maintained. The process gas is exhausted from the process zone following a desired number of process cycles.

In yet another method of depositing a stressed material on a substrate, the substrate is placed in a process zone that is bounded by electrodes of a process chamber. A process gas having silicon-containing gas and nitrogen-containing gas is introduced into the process zone. A pulsed plasma of the process gas is generated by applying voltage pulses across the electrodes bounding the process zone, the voltage pulses each having a duty cycle, and the voltage pulses delivering a high radio frequency voltage to the electrodes at a power level of from about 20 to about 500 Watts.

In a further method of forming a stressed material on a substrate, the substrate is placed in a process zone, a process gas comprising a first component having silane and ammonia and a second component having nitrogen, is introduced into the process zone, and a plasma is formed of the process gas. The volumetric flow ratio of the first component of the process gas to the second component of the process gas is at least about 1:10.

In another version, a stressed material is formed on a substrate by placing the substrate in a process zone, introducing a process gas comprising silane and ammonia into the process zone, and generating a plasma of the process gas. The volumetric flow ratio of silane to ammonia is from about 1:1 to about 1:3, and is sufficiently low to deposit a tensile stressed material having a tensile stress value of at least about 500 MPa.

In yet another version, a stressed material is deposited on a substrate by placing the substrate in a process zone, maintaining the substrate at temperatures from about 450° C. to about 500° C., introducing a process gas having silicon-containing gas and nitrogen-containing gas into the process zone, and forming a plasma of a process gas in the process zone.

In a further version, a stressed material is deposited on a substrate by placing the substrate in a process zone that is bounded by electrodes of a process chamber. A process gas having silicon-containing gas and nitrogen-containing gas is introduced into the process zone, and a plasma of the process gas is generated by applying a high radio frequency voltage across the electrodes bounding the process zone, the high frequency voltage being applied at a frequency in the range of from about 3 MHz to about 60 MHz, and at a power level of less than about 200 Watts.

In yet another version, a stressed material is deposited on a substrate by placing the substrate in a process zone that is bounded by electrodes that are in a substrate support and a chamber wall, and maintaining the substrate support at an electrically floating potential relative to the chamber wall. A process gas having silicon-containing gas and nitrogen-containing gas is introduced into the process zone, and a plasma of the process gas is generated by applying a radio frequency voltage across the electrodes.

In another version, a stressed material is deposited on a substrate by placing the substrate in a process zone that is bounded by electrodes in a substrate support and a gas distributor of a process chamber. A process gas having silicon-containing gas and nitrogen-containing gas is introduced into the process zone through the gas distributor. A negative DC bias voltage is applied to the gas distributor, and a plasma of the process gas is generated.

In a further version, a stressed material is deposited on a substrate by placing the substrate in a process zone that is bounded by electrodes in a substrate support and a gas distributor of a process chamber. A positive DC bias voltage is applied to the substrate support, a process gas having silicon-containing gas and nitrogen-containing gas is introduced into the process zone through the gas distributor, and a plasma of the process gas is generated.

In yet another version, a stressed material is deposited on a substrate by performing a deposition process cycle and an annealing process cycle. In the deposition process cycle, a stressed material is deposited on the substrate by placing the substrate in a process zone, introducing a process gas having silicon-containing gas and nitrogen-containing gas into the process zone, generating a plasma of the process gas, and exhausting the process gas from the process zone. In the annealing process cycle, the deposited stressed material on the substrate is heated to a temperature of at least about 450° C.

In another version, a stressed material is deposited on a substrate by placing the substrate in a process zone, introducing a first process gas and a second process gas into the process zone, generating a plasma of the first and second process gases, and exhausting the first and second process gases from the process zone. The first process gas is introduced at a first flow rate into the process zone and has silicon-containing gas and nitrogen-containing gas. The second process gas is introduced at a second flow rate into the process zone, and has GeH₄, Ar and H₂.

In a further version, a stressed material is deposited on a substrate by placing the substrate in a process zone, introducing a process gas having a first component and a second component into the process zone, generating a plasma of the process gas, and exhausting the process gas from the chamber. The first component is introduced into the process zone at a first flow rate, and has silicon-containing gas and nitrogen-containing gas. The second component is introduced into the process zone at a second flow rate, and has helium or argon. The volumetric flow ratio of the second component to first component is at least about 1:1.

In yet another method, a stressed material is deposited on a substrate by placing the substrate in a process zone that is bounded by electrodes in a process chamber. A process gas having (i) a first component having silicon-containing gas, (ii) a second component having nitrogen and ammonia, and (iii) a third component having argon is introduced into the chamber. A low RF voltage is applied to the electrodes to generate a plasma of the process gas, the low RF voltage having a frequency that is less than about 1 MHz.

In another version, a stressed material is deposited on a substrate by placing the substrate in a process zone bounded by electrodes in a chamber. A process gas having silicon-containing gas and nitrogen-containing gas is introduced into the process zone, and a plasma of the process gas is generated by applying to the electrodes (i) a low radio frequency voltage at a frequency less than about 1 MHz and a power level of at least about 300 Watts, and (ii) a high radio frequency voltage at a frequency of at least about 10 MHz and a power level of at least about 300 Watts.

In another version, a stressed material is deposited on a substrate by placing the substrate in a process zone bounded by electrodes in a process chamber. A process gas having silicon-containing gas and nitrogen-containing gas is introduced into the process zone, and a plasma of the process gas is generated by (i) setting a spacing distance dₛ of the electrodes that is less than about 10.8 mm, and (ii) applying a radio frequency voltage to the electrodes. The process gas is exhausted from the chamber to set a pressure of at least about 1.5 Torr, whereby a compressive stressed layer is deposited on the substrate.

### DRAWINGS

These features, aspects and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1 is a schematic view of an embodiment of a substrate processing chamber that is a PE-CVD deposition chamber;

FIG. 2 is a schematic view of an exposure chamber suitable for exposing a silicon nitride material to a suitable energy beam source;

FIG. 3 is a graph showing the measured tensile stress value of material deposited at increasing substrate temperature;

FIGS. 4A and 4B are graphs showing examples of the effect of the flow rate of SiH₄ and NH₃ on tensile stress values and the thickness uniformity of the deposited material;

FIGS. 5A to 5D are graphs showing examples of the effect of the flow rate of SiH₄ and NH₃ on the tensile stress values, refractive index, deposition rate and thickness uniformity of the deposited material;

FIGS. 6A and 6B are graphs showing the change in deposition rate, uniformity, tensile stress value and refractive index of the deposited material for increasing flow rate of SiH₄ and NH₃;

FIG. 7 is a graph showing the effect of N₂ flow rate on the deposition rate and tensile stress value of the deposited material;

FIG. 8 is a graph showing the change in tensile stress values of deposited silicon nitride with increasing process gas pressure;

FIG. 9 is a graph showing change in tensile stress values of silicon nitride deposited by applying a low radio frequency voltage to the electrodes at different power levels;

FIGS. 10A and 10B are graphs showing the effects of increasing the power level of a high radio frequency voltage applied to the chamber electrodes, on the deposition rate, material thickness uniformity, tensile stress value, and refractive index of the deposited material;

FIG. 11 is a graph showing measured tensile stresses for increasing power level of the high RF voltage and different nitrogen plasma treatment process cycles;

FIG. 12 is a graph showing the tensile stress values and refractive indices obtained for layers deposited under different deposition and nitrogen plasma treatment process cycles;

FIG. 13 is a graph showing the change in tensile stress values of deposited materials with N₂ plasma treatment time;

FIG. 14 is a graph showing the effect of N₂ plasma treatment time on the tensile stress value for processes having different purge and pump cycles;

FIG. 15 is a bar graph showing the change in tensile stress values of material deposited at different process conditions (A, and B) for increasing ultraviolet radiation exposure time;

FIG. 16 is a graph showing a Fourier Transformed Infrared (FTIR) spectrum of a stressed silicon nitride material in the as-deposited state (as dep. - continuous line), and after treatment with ultraviolet radiation (treated film — dashed line);

FIGS. 17A to 17E are graphs showing the increase in tensile stress of deposited silicon nitride materials with time of ultraviolet radiation exposure, and in FIG. 17A, to both single wavelength (Treatment 1) and broadband (Treatment 2) ultraviolet exposure;

FIG. 18 is a graph showing the increase in tensile stress values with electron beam exposure for materials deposited at different process conditions;

FIGS. 19A to 19D are graphs showing the changes in compressive stress value, deposition rate, thickness uniformity and refractive index of the deposited material for increasing volumetric flow ratio of argon to nitrogen; and

FIG. 20 is a simplified cross-sectional view of a substrate showing a partial view of a transistor structure with an overlying deposited tensile stressed silicon nitride material.

### DESCRIPTION

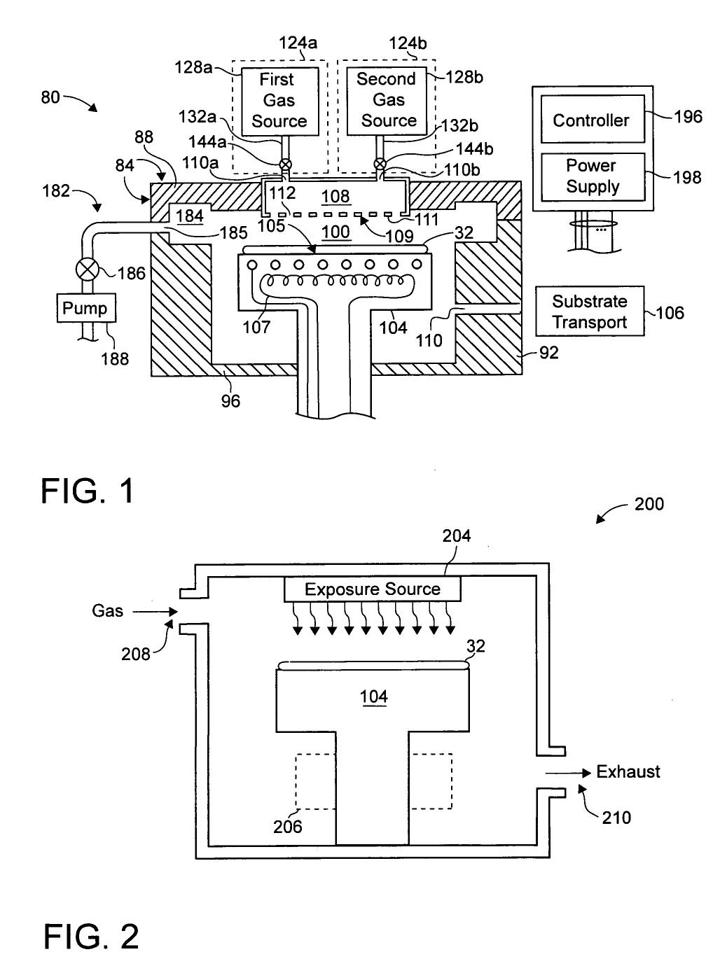

An embodiment of a substrate processing chamber 80 that can be used for depositing stressed materials according to the present invention is schematically illustrated in FIG. 1. While an exemplary chamber is used to illustrate the invention, other chambers as would be apparent to one of ordinary skill in the art may also be used. Accordingly, the scope of the invention should not be limited to the exemplary embodiment of the chamber or other components provided herein. Generally, the chamber 80 is a plasma enhanced chemical vapor deposition (PE-CVD) chamber suitable for processing a substrate 32, such as a silicon wafer. For example, a suitable chamber is a Producer® SE type chamber from Applied Materials, Santa Clara, Calif. The chamber 80 comprises enclosure walls 84, which include a ceiling 88, sidewalls 92, and a bottom wall 96, that enclose a process zone 100. The chamber 80 may also comprise a liner (not shown) that lines at least a portion of the enclosure walls 84 about the process zone 100. For processing a 300 mm silicon wafer, the chamber typically has a volume of about 20,000 to about 30,000 cm³, and more typically about 24,000 cm³.

During a process cycle, the substrate support 104 is lowered and a substrate 32 is passed through an inlet port 110 and placed on the support 104 by a substrate transport 106, such as a robot arm. The substrate support 104 can be moved between a lower position for loading and unloading, and an adjustable upper position for processing of the substrate 32. The substrate support 104 can include an enclosed electrode 105 to generate a plasma from process gas introduced into the chamber 80. The substrate support 104 can be heated by heater 107, which can be an electrically resistive heating element (as shown), a heating lamp (not shown), or the plasma itself. The substrate support 104 typically comprises a ceramic structure which has a receiving surface to receive the substrate 32, and which protects the electrode 105 and heater 107 from the chamber environment. In use, a radio frequency (RF) voltage is applied to the electrode 105 and a direct current (DC) voltage is applied to the heater 107. The electrode 105 in the substrate support 104 can also be used to electrostatically clamp the substrate 32 to the support 104. The substrate support 104 may also comprise one or more rings (not shown) that at least partially surround a periphery of the substrate 32 on the support 104.

After a substrate 32 is loaded onto the support 104, the support 104 is raised to a processing position that is closer to the gas distributor 108 to provide a desired spacing gap distance, dₛ, therebetween. The spacing distance can be from about 2 mm to about 12 mm. The gas distributor 108 is located above the process zone 100 for dispersing a process gas uniformly across the substrate 32. The gas distributor 108 can separately deliver two independent streams of first and second process gas to the process zone 100 without mixing the gas streams prior to their introduction into the process zone 100, or can premix the process gas before providing the premixed process gas to the process zone 100. The gas distributor 108 comprises a faceplate 111 having holes 112 that allow the passage of process gas therethrough. The faceplate 111 is typically made of metal to allow the application of a voltage or potential thereto, and thereby serve as electrode in the chamber 80. A suitable faceplate 111 can be made of aluminum with an anodized coating. The substrate processing chamber 80 also comprises first and second gas supplies 124a, b to deliver the first and second process gas to the gas distributor 108, the gas supplies 124a, b each comprising a gas source 128a, b, one or more gas conduits 132a, b, and one or more gas valves 144a, b. For example, in one version, the first gas supply 124a comprises a first gas conduit 132a and a first gas valve 144a to deliver a first process gas from the gas source 128a to a first inlet 110a of the gas distributor 108, and the second gas supply 124b comprises a second gas conduit 132b and a second gas valve 144b to deliver a second process gas from the second gas source 128b to a second inlet 110b of the gas distributor 108.

The process gas can be energized by coupling electromagnetic energy, for example, high frequency voltage energy to the process gas to form a plasma from the process gas. To energize the first process gas, a voltage is applied between (i) the electrode 105 in the support 104, and (ii) a second electrode 109 which may be the gas distributor 108, ceiling 88 or chamber sidewall 92. The voltage applied across the pair of electrodes 105, 109 capacitatively couples energy to the process gas in the process zone 100. Typically, the voltage applied to the electrode 105, 109 is at a radio frequency. Generally, radio frequencies cover the range of from about 3 kHz to about 300 GHz. For the purposes of the present application, low radio frequencies are those which are less than about 1 MHz, and more preferably from about 100 KHz to 1 MHz, such as for example a frequency of about 300 KHz. Also for the purposes of the present application, high radio frequencies are those from about 3 MHz to about 60 MHz, and more preferably about 13.56 MHz. The selected radio frequency voltage is applied to the first electrode 105 at a power level of from about 10 W to about 1000 W, and the second electrode 109 is typically grounded. However, the particular radio frequency range that is used, and the power level of the applied voltage, depend upon the type of stressed material to be deposited.

The chamber 80 also comprises a gas exhaust 182 to remove spent process gas and byproducts from the chamber 80 and maintain a predetermined pressure of process gas in the process zone 100. In one version, the gas exhaust 182 includes a pumping channel 184 that receives spent process gas from the process zone 100, an exhaust port 185, a throttle valve 186 and one or more exhaust pumps 188 to control the pressure of process gas in the chamber 80. The exhaust pumps 188 may include one or more of a turbo-molecular pump, cryogenic pump, roughing pump, and combination-function pumps that have more than one function. The chamber 80 may also comprise an inlet port or tube (not shown) through the bottom wall 96 of the chamber 80 to deliver a purging gas into the chamber 80. The purging gas typically flows upward from the inlet port past the substrate support 104 and to an annular pumping channel. The purging gas is used to protect surfaces of the substrate support 104 and other chamber components from undesired deposition during the processing. The purging gas may also be used to affect the flow of process gas in a desirable manner.

A controller 196 is also provided to control the activities and operating parameters of the chamber 80. The controller 196 may comprise, for example, a processor and memory. The processor executes chamber control software, such as a computer program stored in the memory. The memory may be a hard disk drive, read-only memory, flash memory or other types of memory. The controller 196 may also comprise other components, such as a floppy disk drive and a card rack. The card rack may contain a single-board computer, analog and digital input/output boards, interface boards and stepper motor controller boards. The chamber control software includes sets of instructions that dictate the timing, mixture of gases, chamber pressure, chamber temperature, microwave power levels, high frequency power levels, support position, and other parameters of a particular process.

The chamber 80 also comprises a power supply 198 to deliver power to various chamber components such as, for example, the first electrode 105 in the substrate support 104 and the second electrode 109 in the chamber. To deliver power to the chamber electrodes 105, 109, the power supply 198 comprises a radio frequency voltage source that provides a voltage having the selected radio frequencies and the desired selectable power levels. The power supply 198 can include a single radio frequency voltage source, or multiple voltage sources that provide both high and low radio frequencies. The power supply 198 and also include an RF matching circuit. The power supply 198 can further comprise an electrostatic charging source to provide an electrostatic charge to an electrode often electrostatic chuck in the substrate support 104. When a heater 107 is used within the substrate support 104, the power supply 198 also includes a heater power source that provides an appropriate controllable voltage to the heater 107. When a DC bias is to be applied to the gas distributor 108 or the substrate support 104, the power supply 198 also includes a DC bias voltage source that is connected to a conducting metal portion of the faceplate 111 of the gas distributor 108. The power supply 198 can also include the source of power for other chamber components, for example, motors and robots of the chamber.

The substrate processing chamber 80 also comprises a temperature sensor (not shown) such as a thermocouple or an interferometer to detect the temperature of surfaces, such as component surfaces or substrate surfaces, within the chamber 80. The temperature sensor is capable of relaying its data to the chamber controller 196 which can then use the temperature data to control the temperature of the processing chamber 80, for example, by controlling the resistive heating element in the substrate support 104.

Different types of stressed materials can be deposited in the exemplary chamber 80. One type of stressed material that is commonly deposited comprises silicon nitride. By silicon nitride it is meant a material having silicon-nitrogen (Si—N) bonds, including materials such as silicon oxy-nitride, silicon-oxygen-hydrogen-nitrogen, and other stoichiometric or non-stoichiometric combinations of silicon, nitrogen, oxygen, hydrogen and even carbon. Exemplary methods to deposit silicon nitride stressed material will be described to illustrate the invention; however, it should be understood that these methods can also be used to deposit other types of materials, including stressed silicon oxide, stressed dielectric layers, and others. Thus, the scope of the present invention should not be limited to the illustrative stressed silicon nitride embodiment described herein.

It has been discovered that both types of stress, namely tensile or compressive, and the stress value of the deposited silicon nitride stressed material can be set in the deposited material by controlling processing parameters or by treating the deposited material, as described below. The processing parameters are described separately or in particular combinations; however, the invention should not be limited to the exemplary separate or combinations described herein, but may include other separate or combinations of parameters as would be apparent to one of ordinary skill in the art.

I. Tensile Stressed Materials

Without being limited by an explanation, it has been discovered that a silicon nitride stressed material having higher stress values can be obtained by reducing the net hydrogen content, or the amount of silicon-hydrogen bonds (Si—H bonds) in the deposited silicon nitride material. It is believed that the lower hydrogen content in the deposited material, which results in a detectably smaller amount of Si—H bonds in the as-deposited silicon nitride material, gives rise to higher tensile stress values in the deposited material. It has further been discovered that several different deposition process parameters, treatments of deposited material, or combinations thereof, can be used to achieve lower hydrogen content in the deposited material, as described herein.

To deposit a tensile stressed silicon nitride material, the process gas introduced into the chamber comprises a first component that includes a silicon-containing gas and a second component that includes a nitrogen-containing gas. The silicon-containing gas can be, for example, silane, disilane, trimethylsilyl (TMS), tris(dimethylamino)silane (TDMAS), bis(tertiary-butylamino)silane (BTBAS), dichlorosilane (DCS), and combinations thereof. For example, a suitable silane flow rate is from about 5 to about 100 sccm. The nitrogen-containing gas can be, for example, ammonia, nitrogen, and combinations thereof. A suitable ammonia flow rate is from about 10 to about 200 sccm. The process gas can also include a diluent gas that is provided in a much larger volume that the reactive gas components. The diluent gas can also serve both as a diluent and at least partially as a reactant nitrogen-containing gas, for example, nitrogen in a flow rate of from about 5000 to about 30,000 sccm. The process gas may also contain additional gases such as an oxygen-containing gas, for example, oxygen, when depositing silicon oxy-nitride materials. Unless otherwise specified, in these processes, typical gas pressures are from about 3 to about 10 Torr; substrate temperatures are from about 300 to 600° C.; electrode spacing is from about 5 mm (200 mils) to about 12 mm (600 mils); and RF power levels are from about 5 to about 100 Watts.

Higher Temperature

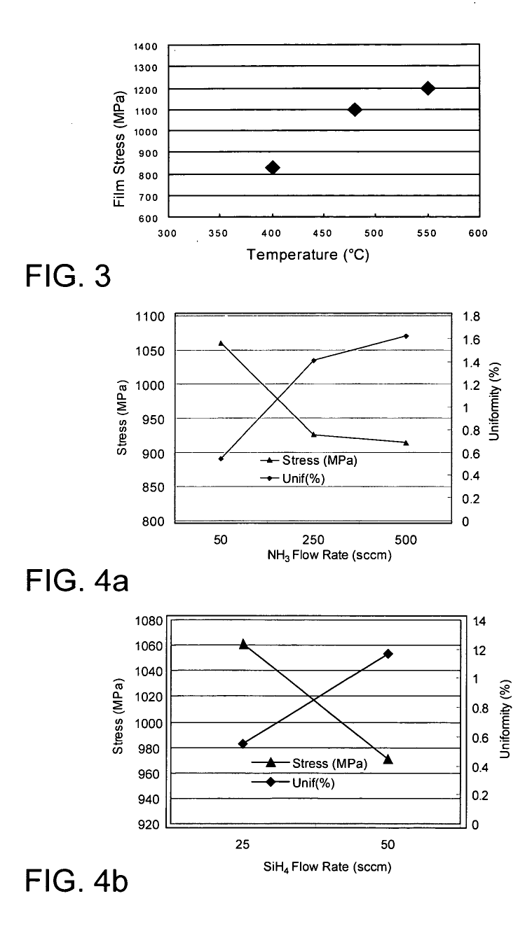

In a first aspect of the invention, it was discovered that lower hydrogen content can be obtained in the deposited silicon nitride material by maintaining higher substrate temperatures during deposition. For example, FIG. 3 shows the effect of substrate temperature on the stress value of the deposited material. At the lowest evaluated temperature of about 400° C., the deposited film exhibited a tensile stress value of slightly over 800 MPa. Increasing the process temperature resulted in increased tensile stress values. For example, a tensile stress value of 1100 MPa was measured for material deposited at the higher temperature of about 475° C., and a tensile stress value of 1200 MPa was measured for material deposited at the highest evaluated process temperature of about 550° C. Thus, increasing process temperature yielded higher tensile stress values for the deposited material. Furthermore, Fourier Transformed Infrared (FTIR) spectroscopy tests conducted on the deposited material indicated that as the deposition process temperature is increased, the peak wave level for both N—H and Si—N bonds in the deposited material decrease, indicating that the lengths of the Si—N and N—H bonds had also decreased. The Si—H bond followed the opposite trend with increasing peak wave levels with higher temperatures. Thus, higher deposition temperatures resulted in lower hydrogen content within the deposited material that is typically identified in the form of reduced levels of Si—H bonds, and higher levels of the desirable Si—N bonds.

However, substrate deposition temperature is limited by the maximum temperatures that the other materials on the substrate 32 can be exposed to without damage. For example, when the stressed silicon nitride material is deposited over a silicide material comprising nickel silicide that is already on the substrate, the temperature of the substrate 32 is maintained at less than about 500° C., and more typically about 480° C. This is because the nickel silicide material would be damaged by exposure to temperatures exceeding 500° C. due to agglomeration of Ni within the silicide material at these higher temperatures which may, for example, undesirably increase the resistivity of the silicide material. Thus, a suitable temperature range of the deposition of tensile stressed silicon nitride over a nickel silicide material is from about 450° C. to about 500° C.

Low Temperature Deposition, Followed by High Temperature Anneal

In another embodiment, deposition of material onto the substrate 32 at a relatively low temperatures followed by rapid thermal annealing of the deposited materials at relatively higher temperatures was found to further increased tensile stress values. Suitable low temperature deposition processes included temperatures less than about 420° C. followed by annealing at annealing temperatures higher than the deposition temperatures. A suitable temperature range for the low temperature deposition process is from about 100 to about 400° C. A suitable temperature for the annealing process is at least about 450° C. and preferably from about 400 to 600° C. The high temperature anneal processes are limited by the melting point or thermal degradation of underlayers of the substrate itself. It is believed that the low temperature deposition reduces the overall thermal exposure of the substrate and the rapid thermal annealing process at high temperatures reduces the H content of the film, thus resulting in increased tensile stresses in the deposited film.

Silane/Ammonia Ratio

Lower hydrogen content can also be obtained in the deposited material by controlling the ratio of the reactive gas components used in the chemical vapor deposition reaction. For example, in silicon nitride deposition, the ratio of silicon-containing gas to nitrogen-containing gas was found to control the stress value of the deposited layer. In one exemplary process of depositing a high tensile stressed silicon nitride material on a substrate 32, the process gas introduced into the chamber 80 contained a silicon-containing gas component comprising silane (SiH₄) a nitrogen-gas component comprising ammonia (NH₃), and a diluent gas component comprising nitrogen (N₂).

FIGS. 4A to 4B are examples of the effect of the NH₃ and SiH₄ flow rates on the tensile stress values and film thickness uniformity. The process conditions included N₂ flow of 20,000 sccm; a pressure of 6 Torr; a power level of 30 Watts; a temperature of 430° C., and electrode spacing of 12 mm (480 mils). In FIG. 4A, the flow rate of NH₃ was maintained at 500 sccm while the flow rate of SiH₄was varied from 25 sccm to 50 sccm. The tensile stress value can be seen to decrease with increasing NH₃ flow rate, from a stress value of a little under 900 MPa at a flow rate of about 50 sccm to a stress value of over 1050 MPa at a flow rate of about 500 sccm. The thickness uniformity of the deposited layer increases with increasing NH₃ flow rate, from a uniformity of less than 0.6% at a flow rate of about 50 sccm, to a uniformity of about 1.6% at a flow rate of about 500 sccm. FIG. 4B shows tensile stress values which were measured for material deposited at the flow rates of NH₃ varying from 50 sccm to 500 sccm and with a constant flow rate of SiH₄ of 25 sccm. The tensile stress values can be seen to decrease with increasing SiH₄ flow rate, from a stress value of about 1060 MPa at a SiH₄ flow rate of about 25 sccm, to a stress value of a little under 980 MPa at a flow rate of about 50 sccm. The thickness uniformity percentage increased with increasing flow rate of the SiH₄ gas, from a uniformity percentage of about 0.5% at about 25 sccm of SiH₄, to a uniformity percentage of about 1.2% at a flow rate of SiH₄ of about 50 sccm.

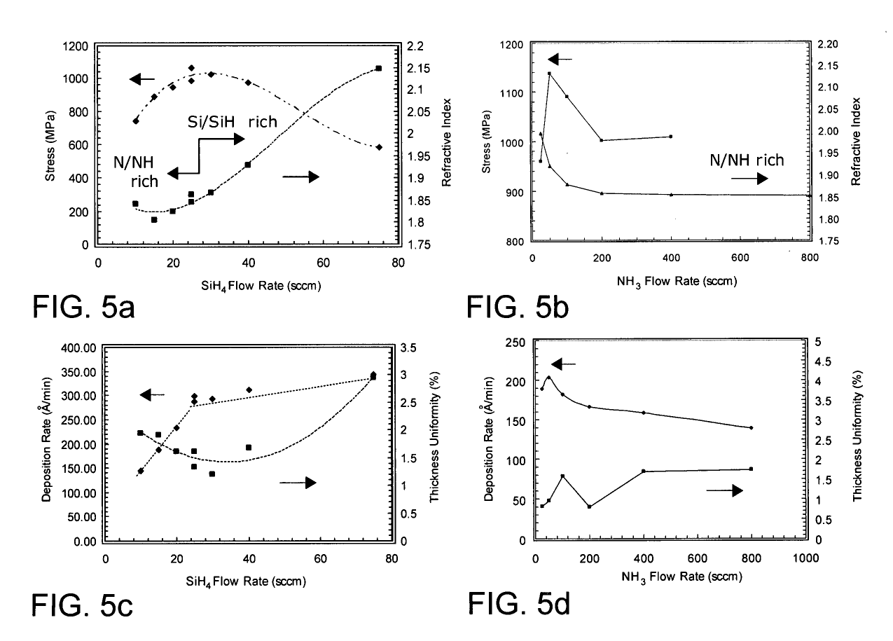

FIGS. 5A to 5D are examples of the effect of SiH₄ and NH₃ flow rate on the tensile stress values, refractive index, deposition rate and thickness uniformity. These figures illustrate that, generally, the lower ratios of SiH₄ to NH₃ provide higher tensile stress values. FIG. 5A shows the effect on the tensile stress value and refractive index for increasing flow rates of SiH₄ that provide Si/SiH rich environments versus lower flow rates of SiH₄ that provide N/NH rich environments. In general, the tensile stress value increased up to SiH₄ flow rates of about 21 sccm, after which it decreased; while the refractive index generally increased with increasing flow of SiH₄. FIG. 5B shows that for increasing flow rates of NH₃ (N/NH rich environments) versus lower flow rates of NH₃ (Si/SiH rich environments), both the measured tensile stress and refractive index substantially leveled out at about 200 sccm of NH₃. FIG. 5C shows that deposition rate generally increases, and uniformity decreases, with increasing SiH₄ flow rate to a flow rate of about 40 sccm, after which the uniformity increased. FIG. 5D shows that the deposition rate generally decreased with increasing flow rate of NH₃, whereas the uniformity percentage increased until a flow of about 400 sccm of NH₃, after which the uniformity percentage substantially leveled out.

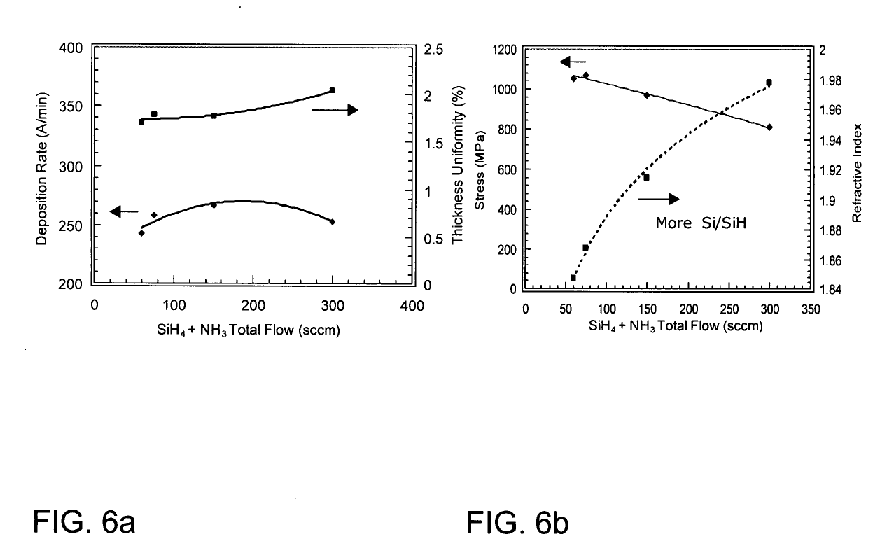

FIGS. 6A and 6B show the effects of the overall flow rate of SiH₄ and NH₃ on deposition rate, thickness uniformity (%), tensile stress value and refractive index for the previously listed process conditions. FIG. 6A shows that the thickness uniformity generally increased with increasing total flow, whereas the deposition rate increased up to a total flow rate of about 150 sccm, after which the deposition rate decreased. FIG. 6B shows that the tensile stress value generally decreased with increasing total flow, which the refractive index generally increased with increasing total flow of SiH₄ and NH₃ the effect on the tensile stress value and refractive index of increasing the overall flow rate of SiH₄ and NH₃.

Thus, decreasing the ratio of the flow rate of SiH₄ to NH₃ deposits materials having higher tensile stress values. Consequently, the ratio of the volumetric flow rate of silane to ammonia is selected to be sufficiently low to deposit a tensile stressed material which, for example, has a tensile stress of at least about 500 MPa. Preferably, the ratio of silane to ammonia is from about 1:1 to about 1:3, and more preferably about 1:2. A suitable composition comprises silane in a volumetric flow rate of 25 sccm and ammonia in a volumetric flow rate of 50 sccm.

Nitrogen Diluent Gas

A diluent gas component comprising nitrogen can also be added to the aforementioned process gas in a sufficiently large volume. The nitrogen diluent gas is referred to as a diluent gas because of the much larger relative volume of this gas that is used as compared to other process gas components, but nitrogen can actually serve as both a diluent and a reactive gas. Lower hydrogen content is obtained in the deposited material by controlling the ratio of the volume of diluent gas present in the chamber to the other gas components during deposition.

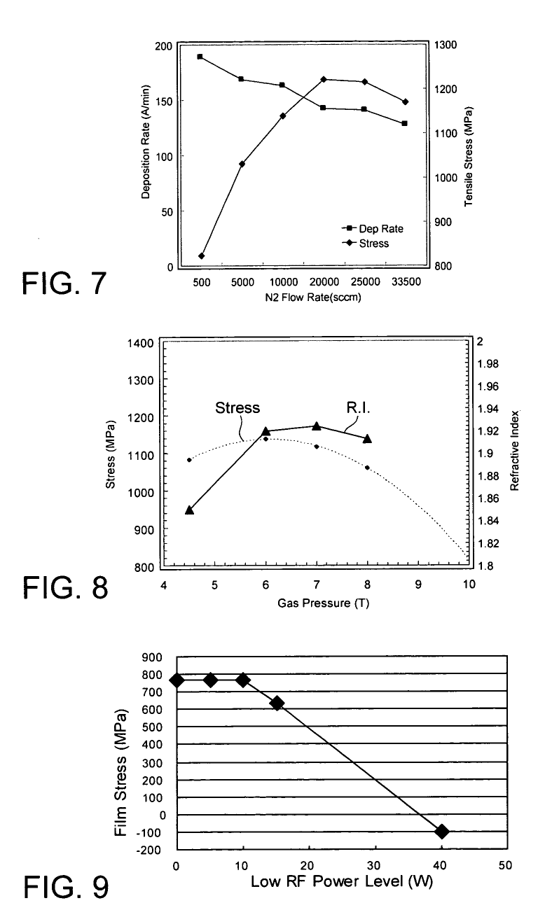

The effect of N₂ flow rate on the deposition rate and tensile stress value of the deposited material is shown in FIG. 7. The deposition rate generally decreases with increasing N₂ flow rate, from a rate of just a little under 200 angstroms/minute at a N₂ flow rate of about 500 sccm, to a deposition rate of about 125 angstroms/minute at a N₂ flow rate of about 33,500 sccm. The tensile stress value of the deposited material at flow rates of N₂ of 500 sccm, was relatively low at about 800 MPa. The tensile stress value increases with increasing N₂ flow rate to above 100 MPa at a flow rate of about 5000 sccm and above 1100 MPa at 10,000 sccm. The highest tensile stress value of about 1200 MPa were obtained at N₂flow rates from about 20,000 to about 25,000 sccm. At flow rate levels above 25,000 sccm, namely at 33,500 sccm of N₂, the tensile stress value of the deposited material starts to decrease to below 1200 MPa. Accordingly, for the present chamber volume of about 25,000 sccm, the highest tensile stress values were achieved at an N₂ flow rate of from about 20,000 to about 25,000 sccm. Thus, for tensile stressed material, the flow rate per unit chamber volume of diluent gas, such as N₂, was from about 0.8 to about 1.

In one embodiment, the ratio of the combined volumetric flow rates of silane and ammonia to the flow rate of nitrogen is maintained at least about 1:10 to provide optimal tensile stresses in the deposited material. For example, when the combined volumetric flow rate of silane and ammonia is 75 sccm, the volumetric flow rate of nitrogen should be at least about 7500 sccm, and more typically from about 10,000 to about 20,000 sccm. Without being limited by the explanation, it is believed that the higher nitrogen content of the process gas results in lower hydrogen content, and consequently higher tensile stresses, of the deposited material. The larger amount of diluent nitrogen in the process gas increases the time during which silicon and nitrogen plasma species actually stay in the gas phase, thereby increasing the likelihood of forming silicon-nitrogen (Si—N) bonds in the deposited material and reducing the number of Si—H bonds formed in the material.

Gas Pressure Range

FIG. 8 shows the effect of increasing process gas pressure in the chamber on the resulting tensile stress value and refractive index of the deposited material. Generally, between about 4 and 8 Torr, the tensile stress values induced in the deposited material remain relatively flat around 1100 MPa (line (a)). Pressure levels of 6 Torr give the highest tensile stress, while pressures below 6 Torr and above 6 Torr give lower tensile stress values. At gas pressures exceeding 8 Torr, tensile stress values substantially decrease. Increased gas pressure also gives higher refractive indexes up until a pressure of about 7 Torr, after which the refractive index decreases. Thus, the gas pressure is preferably from about 4 Torr to about 8 Torr.

Low Power Levels of High RF Voltage

A plasma is formed from the process gas by applying a high radio frequency voltage to the electrode 105 and grounding the second electrode 107. High radio frequency refers to frequencies in the range of from about 3 MHz to about 60 MHz. Activation of the CVD reaction by generating a plasma from the process gas is generally advantageous because it allows relatively lower temperature processing in comparison to thermally activated CVD processes. In the described example, a high radio frequency voltage is applied to the electrodes 105, 109 at a frequency of 13.56 MHz.

For depositing a tensile stressed silicon nitride material, substantially only the high frequency voltage applied to the electrode 105. Low radio frequencies that are less than about 1 MHz, such as a frequency of 300 kHz, are not applied to the electrode because it was experimentally determined that increasing the power level of the low frequency voltage applied to the electrodes during deposition results in the deposition of material having an undesirably low tensile stress value. For example, FIG. 9 shows the measured tensile stress values of silicon nitride materials deposited using a low radio frequency voltage applied across the electrodes 105, 109 at different power levels. As shown, silicon nitride materials deposited with a low RF voltage generated plasma at a power levels of less than 10 Watts resulted in an essentially flat tensile stress value that was slightly below 800 MPa. Increasing the power level of the low RF voltage resulted in the deposition of films with lower tensile stress values. For example, a material deposited using a low frequency voltage applied at a power level of about 15 watts exhibited a stress value of less than about 600 MPa, and a material deposited at the even higher power levels of 40 Watts exhibited a negative compressive stress value of about −100 MPa. Thus, for tensile stressed material deposition, substantially only high RF voltages were applied across the electrodes 105, 109 and not low RF voltages.

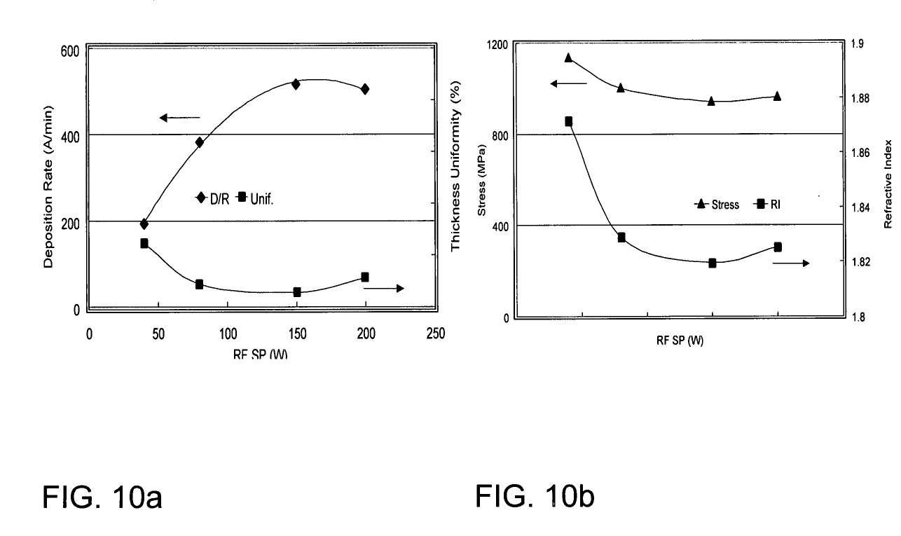

Furthermore, it was also determined that the high RF voltages should be applied at relatively low power levels. FIGS. 10A and 10B illustrate the effects of increasing the power level of the high radio frequency power levels on the deposition rate, material thickness uniformity, tensile stress value, and refractive index of the deposited material. FIG. 10A shows an increase in the deposition rate until a power level of 150 Watts, and a decrease in the uniformity percentage until a power level of 150 Watts. FIG. 10B shows a decrease in the tensile stress values and refractive index with increasing high frequency power level. It is believed that the power level of the high RF voltage applied to the chamber electrodes 105, 109 should be sufficiently low to reduce bombardment of the substrate 32 by energetic plasma species, which reduces the tensile stress value of the material being deposited. However, the power level of the high RF voltage should not be too low otherwise the plasma is unstable, and thus, the power should be sufficiently high to create a stable plasma. Based on these requirements, the power level of the applied high RF voltage is preferably less than about 200 watts, and more preferably from about 10 to about 100 watts.

The aforementioned process conditions deposited a tensile stressed silicon nitride material having a tensile stress value that exceeded 1.2 GPa, which is significantly higher than the previously obtained tensile stress values of 100 to 1000 MPa. It is believed that the higher tensile stress values resulted from lower hydrogen content in the as-deposited silicon nitride material, which in turn occurred as a result of using the process condition combination of a selected volumetric flow ratio of silane to ammonia, high diluent gas content, high processing temperature, and the application of the high radio frequency voltage to the chamber electrodes.

Floating Potential for Substrate Support

Maintaining the substrate support that supports the substrate at a floating potential also improves the tensile stress values of the deposited material, particularly at greater values of the high RF power levels. For example, Table I shows the higher tensile stress values that were obtained at high power levels of the high RF voltage applied to the support 104 below the substrate 32. A high radio frequency of 13.56 MHz and power levels exceeded 200 Watts. Although high power levels of the high RF voltage generally result in low tensile stress in the deposited material, application of a floating potential on the substrate support 104 provided improved tensile stress values which exceeded 1.1 GPa.

TABLE I
High RF Power with Floating Potential on Substrate Support

| HF Power | Time | Spacing | Thickness | Dep Rate | Unif | RI | Stress |
|---|---|---|---|---|---|---|---|
| 200 W | 480 s | 15.25 mm | 610.33 | 76.3 | 16.789 | 1.8847 | 1.13 GPa |
| 300 W | 240 s | 15.25 mm | 558.99 | 139.7 | 5.46 | 1.8662 | 1.12 GPa |

In this version, the substrate support 104 can have any one of the described structures, including a metal block with a dielectric coating, an electrostatic chuck, and a metal block with embedded resistant heater element.
Applying DC Bias Voltage

A DC (direct current) bias voltage can be applied either to the gas distributor 108 or the substrate support 104 to further reduce ion bombardment of the substrate 32, and thereby increase the tensile stress values of the deposited material. The DC bias voltage serves to reduce the acceleration velocity of the charged plasma species toward the substrate. To apply a DC bias voltage to the gas distributor 108, the power supply 200 includes a DC bias voltage source that is electrically connected to the faceplate 111 of the gas distributor. Typically, a negative DC bias voltage is applied to the gas distributor 108 to reduce one bombardment of the substrate 32. Suitable negative DC bias voltage levels that can be applied to the gas distributor 108 are less than about 200 volts, and more preferably from about 25 to about 100 volts.

The DC bias applied to the substrate support 104 to reduce ion bombardment of the substrate 32 is typically a positive DC bias voltage. The positive DC bias voltage reduces the net acceleration voltage applied on the plasma species traveling towards a substrate 32, thus, reducing the kinetic energy of the plasma species bombarding the substrate 32. Suitable positive DC bias voltage levels that can be applied to the support 32 are at least about 25 volts, and more preferably from about 50 to about 100 volts.

Nitrogen Plasma Treatment Cycles

It was further discovered that the stress values of the as-deposited silicon nitride material could be further increased by treating the deposited silicon nitride film with a nitrogen plasma treatment cycle. Such a treatment cycle can be performed by modifying the deposition process to have two process cycles. In the first or deposition process cycle, a process gas comprising a first component comprising silicon-containing gas and nitrogen-containing gas, and a second component comprising a diluent nitrogen gas, is introduced into the chamber and a plasma is formed from the process gas by applying a high frequency voltage to the chamber electrodes. In the second or nitrogen plasma treatment cycle, the flow of the first component of the process gas which includes the silicon-containing gas and the nitrogen-containing gas is shut off or substantially terminated; while the flow of the second component comprising the diluent nitrogen gas is still left on, and the high frequency voltage supplied to the electrodes to form the plasma is also maintained. These two process cycles are repeated a number of times during deposition of the silicon nitride material.

Again, without being limited by the explanation, it is believed that the nitrogen plasma cycles further reduce the hydrogen content in the deposited silicon nitride. It is believed that the nitrogen plasma cycle promotes the formation of silicon-nitrogen bonds in the deposited silicon nitride material by removing silicon-hydrogen bonds from the deposited material. However, since the nitrogen plasma treatment can only affect a thin surface region of the deposited silicon nitride film, a nitrogen treatment cycle is formed after short deposition process cycles in which only a film of silicon nitride is deposited on the substrate that is sufficiently thin to allow nitrogen plasma treatment to penetrate substantially the entire thickness of the deposited film. If the nitrogen plasma treatment was performed after deposition of the entire thickness of the silicon nitride film, only a thin surface region of the deposited material would be properly treated.

The modified deposition process comprises a sufficient number of deposition cycles followed by plasma treatment cycles to achieve the desired film thickness. For example, a deposition process comprising twenty (20) process cycles that each comprises a first deposition cycle and a second nitrogen plasma treatment cycle, deposited a tensile stressed silicon nitride material having a thickness of 500 angstroms. Each deposition cycles was performed for about 2 to about 10 seconds and more typically about 5 seconds; and each nitrogen plasma treatment cycle was performed for about 10 to about 30 seconds, and more typically 20 seconds. The resultant deposited tensile stressed silicon nitride material had a thickness of 500 angstroms, and the tensile stress value of the deposited material was increased by the nitrogen plasma treatment to 1.4 GPa. This represented a 10 to 20% improvement over the tensile stress of the as-deposited silicon nitride material.

TABLE II
Tensile Film Stress with Temperature and Nitrogen Plasma Treatment

| Temperature | 400° C. | 430° C. | 450° C. | 480° C. | 500° C. |
|---|---|---|---|---|---|
| Baseline | 1.0 GPa | 1.1 GPa | 1.2 GPa | 1.3 GPa | 1.35 Gpa |
| (Single | | | | | |
| Material) | | | | | |
| NPT (1) | 1.3 GPa | 1.35 GPa | 1.44 GPa | 1.44 GPa | 1.43 GPa |
| (20s Treat) | | | | | |
| NPT (2) | 1.3 GPa | 1.35 GPa | 1.4 GPa | 1.4 GPa | 1.43 GPa |
| (10s Treat) | | | | | |

Table II shows the improvement in tensile stress of a deposited silicon nitride material with increased substrate temperature during deposition, and with/without multiple nitrogen plasma treatment cycles. The baseline (single material) silicon nitride film was deposited in a single deposition process cycle using the process conditions described above, without nitrogen plasma treatment cycles. The baseline film showed an increase in tensile stress from 1 GPa to about 1.35 GPa as the substrate temperature was increased from 400 to 500° C. The NPT (nitrogen plasma treatment) films were deposited with multiple deposition and nitrogen plasma process cycles—where NPT (1) corresponds to 20 second nitrogen plasma treatment cycles and NPT (2) corresponds to 10 second nitrogen plasma treatment cycles. It is seen that for both NPT films, the tensile stress increased from the baseline film with the nitrogen plasma treatment and also increased with substrate temperature.

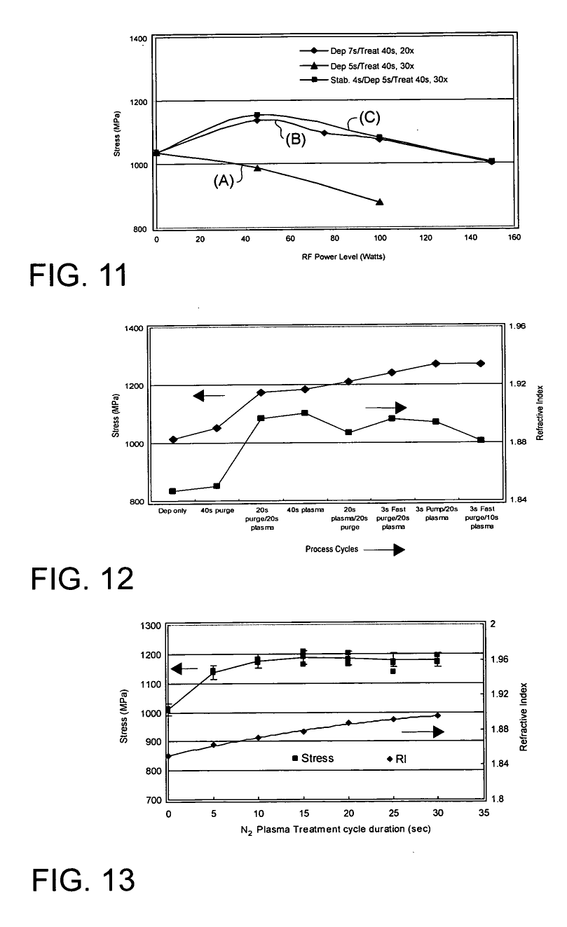

FIG. 11 shows the effect of increasing power level of the high RF voltage applied to the electrodes 105, 109, for different nitrogen plasma treatment process conditions, on the tensile stress values of the deposited materials. The first process (A) comprised a deposition stage for 7 seconds, followed by a plasma treatment stage of 40 seconds, repeated for 20 cycles. The second process (B) involved a deposition stage for 5 seconds, followed by plasma treatment for 40 seconds, repeated for 30 cycles. The third process involved plasma stabilizing stage for 4 seconds, deposition for 5 seconds, and plasma treatment for 40 seconds, for 30 cycles. The first and third processes resulted in the highest tensile stress values, when the high radio frequency was set to a power level of a little over 40 Watts, with tensile stress values decreasing on either side of that peak level. The third process steadily decreased in tensile stress value for increasing power levels from a tensile stress value of a little over a 1000 MPa at a power of 0 Watts to 900 MPa at a power of 100 Watts. Thus a power level of 20 to 60 watts and more preferably 45 watts was selected for nitrogen plasma/deposition processes.

FIG. 12 shows the tensile stress values and refractive indices obtained for layers deposited under different deposition processes and different nitrogen plasma treatment cycles. The top line indicates the measured tensile stress values and the bottom line indicated the measured refractive indices. The processes included: a deposition only process; a process with a 40 second purge to see the effect without RF power, that is only thermal impact; a process with a 20 second purge then 20 second plasma step; a process with a 40 second plasma step; a process with a 20 second plasma step then 20 second purge; a process with a 3 second fast purge than 20 second plasma step; a process with a 3 second pump and 20 second plasma step, and a process with a 3 second fast purge and 10 second plasma step. The highest tensile stress values were achieved with the 3 second pump, 20 second plasma and 3 second fast purge, 10 second plasma processes. The lowest tensile stress values were measured for the deposition only and 10 second purge processes. Generally, the stress value obtained maximizes and evens out for plasma treatment durations longer than 10 sec; however, the stress values do not saturate for treatment durations that were longer than 20 sec when a pump down cycle was added.

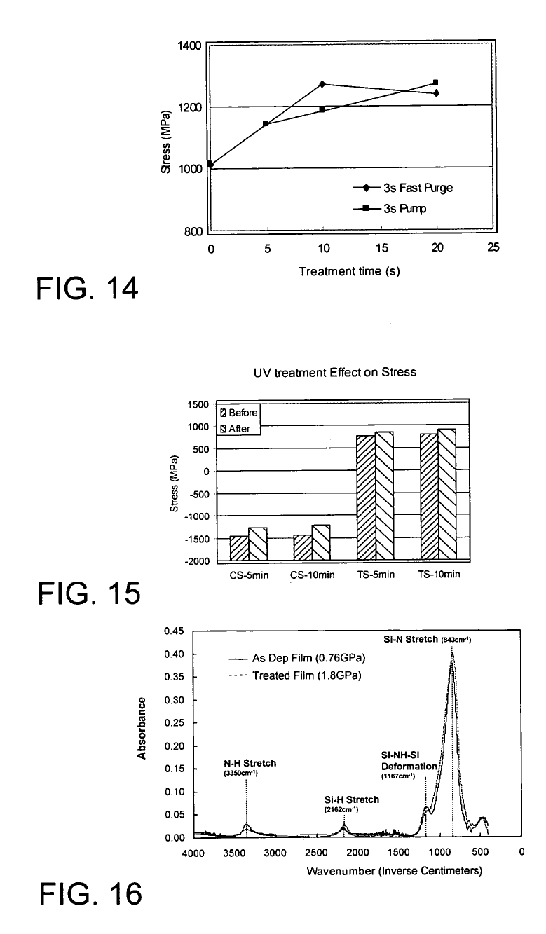

FIG. 13 shows the effect of the duration of N₂ plasma treatment on the tensile stress values of deposited materials. The tensile stress values increase until a treatment duration of about 10 seconds is reached, after which the tensile stress values appears to “saturate” and do not get much larger. The refractive index increases slightly with increasing treatment time. FIG. 14 shows the effect of the treatment duration on the tensile stress value for processes having a 3 second fast purge and a 3 second pump. The tensile stress values in FIG. 14 do not appear to “saturate” as much as those in FIG. 13, even for treatment times up to about 20 seconds.

Pulsed Plasma at High RF Voltages

A stressed material having higher stress values can be deposited by pulsing the radio frequency voltage applied to the electrodes 105,109 of the chamber 80. The pulsed plasma also provided more uniform to deposition thickness and stress values across the deposited material. For the deposition of tensile stressed films, a high radio frequency voltage is used for the pulsed deposition process. The process gas comprises a silicon-containing gas and a nitrogen-containing gas as described above. For example, the silicon-containing gas can include silane, the nitrogen-containing gas can include ammonia, and optionally nitrogen can also be added to deposit a stressed layer comprising silicon nitride. While a particular material, such as silicon nitride, is provided as an illustrative example, it should be understood that other stressed materials can also be deposited by the pulsed CVD method; thus, the scope of the present invention should not be limited to the illustrative example.

The pulsed plasma of the process gas is generated by applying voltage pulses of a radio frequency voltage across the electrodes bounding the process zone in the chamber. The voltage pulses each have a duty cycle, which is the ratio of the pulse duration (T₁) to the pulse period (T₂). In a pulsed waveform, the pulse duration is the interval between (a) the time, during the first transition, that the pulse amplitude reaches a specified fraction (level) of its final amplitude, and (b) the time the pulse amplitude drops, on the last transition, to the same level. Generally, the interval between the 50% points of the final amplitude is usually used to determine or define pulse duration. Preferably, the voltage pulses are rectangular pulses, but they can also have other shapes, such as for example, square or sinusoidal pulses. The pulsed RF power is provided at a power level of from about 100 to about 500 Watts. The selected power level is relatively high because it is believed that at the high-power levels, SiH₄ and NH₃ will dissociate more completely and thus reduce the overall hydrogen content of the deposited film.

The duty cycle of the voltage pulses can also be selected to control the type and level of stress of the deposited stressed layer. Different pulse types, radio frequency level, wattage, and the ratio T₂/T₁ can be selected to provide the level of stress in the deposited stressed film. Generally, it was determined that higher tensile stress values were achieved using smaller duty cycles. Smaller duty cycles can be achieved by reducing the pulse duration (T₁) and/or increasing the pulse period (T₂), or vice versa. Preferably, the duty cycle is less than about 60%. The duty cycle range is preferably from about 10% to about 50%, and more preferably from about 20%. For such duty cycles, the pulse frequency ranges from 10 to 1000 Hz. In one preferred embodiment, the duty cycle is 20% (e.g. 0.25) for a pulse train at 50 Hz in which the pulse duration is 4 ms (e.g. 1 μs) and the pulse period is 20 ms (e.g. 4 μs).

In the pulsed plasma processes, a high RF voltage having a frequency in the range of from about 3 MHz to about 60 MHz, was applied across the electrodes 105, 109. The high RF voltage was applied at a power level of from about 100 to about 1000 Watts. A suitable process gas comprises silane, ammonia, nitrogen and optionally argon, in the flow ranges described herein.

Ultraviolet Radiation Exposure

The tensile stress of an as-deposited silicon nitride material can be further increased by treating the deposited material with exposure to a suitable energy beam, such as ultraviolet radiation or electron beams. It is believed that ultraviolet and electron beam exposure can be used to further reduce the hydrogen content in the deposited material. The energy beam exposure can be performed within the CVD chamber itself or in a separate chamber. For example, a substrate having the deposited stressed material could be exposed to ultraviolet or electron beam radiation inside the CVD processing chamber. In such an embodiment, the exposure source could be protected from the CVD reaction by a shield or by introducing the exposure source into the chamber subsequent to the flow of process gas. The ultraviolet or electron beams could be applied to the substrate, in-situ in the CD deposition chamber during a CVD reaction to deposit the stressed material. In this version, it is believed that ultraviolet or e-beam exposure during the deposition reaction would disrupt undesirable bonds as they are formed, thereby enhancing the stress values of the deposited stressed material.

FIG. 2 shows an exemplary embodiment of an exposure chamber 200 which can be used to expose a substrate 32 to ultraviolet radiation or electron beam treatment. In the version shown, the chamber 200 includes a substrate support 104 moveable between a released position distal from the exposure source 204, and a lifted position proximate to the source 204 to allow adjustment of the spacing therebetween. A substrate support 104 supports the substrate 32 in the chamber 200. During insertion and removal of the substrate 32 from the exposure chamber 200, the substrate support 104 can be moved to a loading position, and thereafter, during exposure of the substrate 32 having the deposited silicon nitride material to ultraviolet radiation or electron beams, the support 104 is raised into the lifted position to maximize exposure levels. The chamber 200 further comprises a heater 206, such as a resistive element, which can be used to heat the substrate 32 to a desired temperature during exposure of the substrate 32. A gas inlet 208 is provided to introduce a gas into the exposure chamber 200 and a gas outlet 210 is provided to exhaust the gas from the chamber 200.

The exposure chamber 200 further includes an exposure source 204 that provides a suitable energy beam, such as ultraviolet radiation or electron beams. A suitable ultraviolet radiation source can emit a single ultraviolet wavelength or a broadband of ultraviolet wavelengths. A suitable single wavelength ultraviolet source comprises an excimer ultraviolet source that provides a single ultraviolet wavelength of 172 nm or 222 nm. A suitable broadband source generates ultraviolet radiation having wavelengths of from about 200 to about 400 nm. Such ultraviolet sources can be obtained from Fusion Company, USA or Nordson Company, USA. The stressed silicon nitride material may be exposed to ultraviolet radiation having other wavelengths that are generated by lamps that contain gas that radiates at specific wavelengths when electrically stimulated. For example, suitable ultraviolet lamp may comprise Xe gas, which generates ultraviolet radiation having a wavelength of 172 nm. In other versions, the lamp may comprise other gases having different corresponding wavelengths, for example, mercury lamps radiate at a wavelength of 243 nm, deuterium radiates at a wavelength of 140 nm, and KrCl₂ radiates at a wavelength of 222 nm. Also, in one version, generation of ultraviolet radiation specifically tailored to modify the stress value in the deposited stressed material can be accomplished by introducing a mixture of gases into the lamp, each gas capable of emitting radiation of a characteristic wavelength upon excitation. By varying the relative concentration of the gases, the wavelength content of the output from the radiation source can be selected to simultaneously expose all of the desired wavelengths, thus minimizing the necessary exposure time. The wavelength and intensity of the ultraviolet radiation can be selected to obtain predetermined tensile stress value in the deposited silicon nitride material.

The CVD deposition chamber 80 and exposure chamber 200 may also be integrated together on a multi-chamber processing platform (not shown) served by a single robot arm. The exposure source 204 and the support of the exposure chamber 200, and the components of the CVD deposition chamber 80 that include the substrate support 104, motor, valves or flow controllers, gas delivery system, throttle valve, high frequency power supply, and heater 206, and the robot arm of the integrated processing system, may all be controlled by a system controller over suitable control lines. The system controller relies on feedback from optical sensors to determine the position of movable mechanical assemblies such as the throttle valve and substrate support 104 which are moved by appropriate motors under the control of the controller.

For exposure treatment in the described exposure chamber 200, a substrate having a silicon nitride material according to any of the deposition processes described or other deposition processes known in the art, is inserted into the exposure chamber 200 and placed upon the substrate support 104 in the lowered position. The substrate support 104 is then raised to a lifted position, the optional heater 206 in the support powered on, and the exposure source 204 is activated. During exposure, a gas may be circulated through the exposure chamber 200, such as helium, to improve thermal heat transfer rates between the substrate and the support. Other gases may also be used. After a period of radiation exposure, the exposure source 204 is deactivated and the substrate support 104 is lowered back into the released position. The substrate bearing the exposed silicon nitride stressed material is then removed from the exposure chamber 200.

FIG. 15 is a bar graph showing the effect of ultraviolet radiation treatment on the tensile stress values of materials deposited at different process conditions including A: compressive film (45 sccm SiH4/600 sccm NH3/2000 sccm He/30 W HF/30 W LF/2.5 T/480 mils/430 C); and B: tensile film (75 sccm SiH4/1600 sccm NH3/5000 sccm N2/50 W HF/5 W LF/6 T/480 mils/430 C). Different broadband UV treatment times at 400° C. of 5 minutes and 10 minutes were used. For all deposited films, ultraviolet radiation exposure increased tensile stress values, with the greatest improvement occurring for the materials having the lowest tensile stress values, namely materials A and B. A and B increased in a tensile stress of level from about −1500 MPa to around about −1300 MPa. Materials C and D also increased. Thus, the ultraviolet treatment can increase the tensile stress value for deposited materials.

It was determined that exposure of the deposited silicon nitride material to ultraviolet radiation or electron beams is capable of reducing the hydrogen content of the deposited material, and thereby increasing the tensile stress value of the material. It is believed that exposure to ultraviolet radiation allows replacement of unwanted chemical bonds with more desirable chemical bonds. For example, the wavelength of UV radiation delivered in the exposure may be selected to disrupt unwanted hydrogen bonds, such as the Si—H and N—H bond that absorbs this wavelength. The remaining silicon atom then forms a bond with an available nitrogen atom to form the desired Si—N bonds. For example, FIG. 16 shows a Fourier Transformed Infrared spectrum (FTIR) of a stressed silicon nitride material in the as-deposited state (as dep. - continuous line), and after treatment with ultraviolet radiation (treated film — dashed line). From the FTIR spectrum, it is seen that after treatment with the ultraviolet radiation, the size of both the N—H stretch peak and the Si—H stretch peak significantly decrease, while the size of the Si—N stretch peak increases. This demonstrates that after ultraviolet treatment, the resultant silicon nitride material contains fewer N—H and Si—H bonds, and an increased number of Si—N bonds which are desirable to increase the tensile stress of the deposited material.

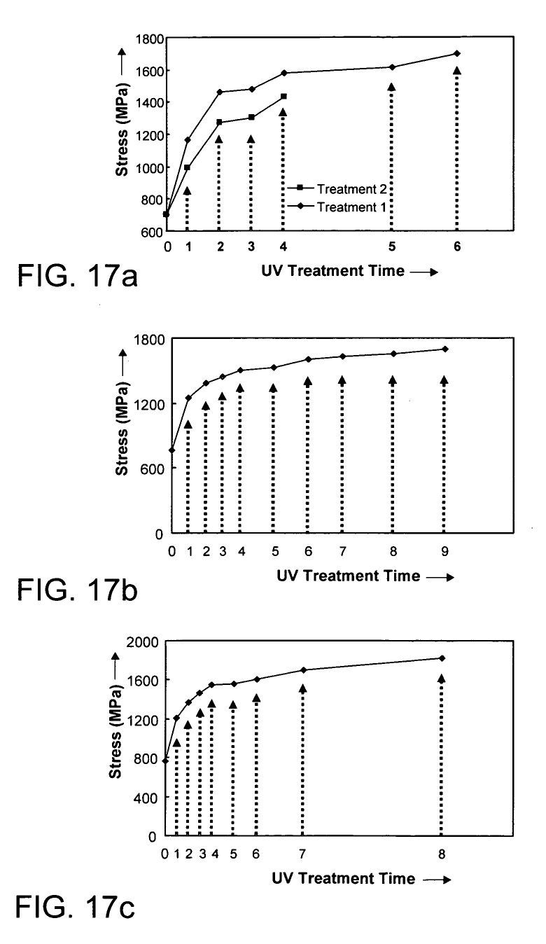

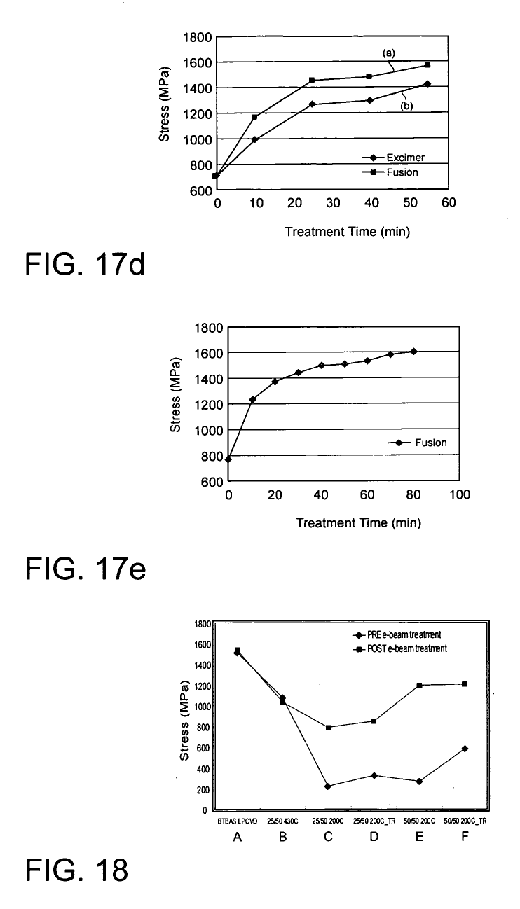

FIGS. 17A to 17E show the improvement in tensile stress value of an as-deposited silicon nitride material that is subjected to different periods of ultraviolet exposure treatment times. The silicon nitride material of FIG. 17A was deposited under the following process conditions 60 sccm flow rate of silane; 900 sccm flow rate of ammonia; 10,000 sccm flow rate of nitrogen; 6 Torr process gas pressure; electrode power level of 100 watt; and electrode spacing of 11 mm (430 mils). The tensile stress of the deposited silicon nitride film was measured in the as-deposited state to be about 700 MPa. The points label 0 to 6 on the x-axis each correspond to different ultraviolet treatment time of 0 minutes (as deposited), 10 minutes, 30 minutes, 45 minutes, one hour, two hours, and three hours, respectively. The as-deposited silicon nitride material of the line labeled with tetrahedrons (treatment 1) was exposed to a broadband ultraviolet radiation source, while the as-deposited silicon nitride material of the line labeled with squares (treatment 2) was exposed to a single wavelength ultraviolet source at 172 nm. It was determined that the broadband ultraviolet radiation source provided increased tensile stress in the deposited material as compared with a single wavelength ultraviolet radiation source.

Generally, as ultraviolet treatment time increased, the tensile stress of the as-deposited film also increased from the original value of 700 MPa to values exceeding about 1.6 GPa. The silicon nitride material of FIGS. 17B and 17C were deposited under the same conditions as the sample shown in FIG. 17A, with the following exceptions—the sample of FIG. 17B was deposited using 60 sccm flow rate of silane; 600 sccm flow rate of ammonia; and electrode power level of 150 watts; and the sample of FIG. 17C was deposited using 60 sccm flow rate of silane; 300 sccm flow rate of ammonia; and an electrode power level of 150 watts. In FIGS. 17B and 17C, the as-deposited material was treated only with a broadband ultraviolet radiation, and the treatment times also varied from 0 minutes to 3 hours but at different time intervals corresponding to 8 or 9 segments, as shown. The best result obtained is shown in FIG. 17C, where the as-deposited silicon nitride material increased in tensile stress after approximately three hours of ultraviolet exposure from 800 MPa to 1.8 GPa, which was almost double the original tensile stress value.

The material deposited shown in FIG. 17D was deposited using 60 sccm flow rate of silane; 900 sccm flow rate of ammonia; 10,000 sccm nitrogen; electrode power of 100 watt; pressure of 7 Torr; and 11 mm spacing. Line (a) was treated with a Fusion H UV light source which provided UV wavelengths of about 200 to 400 nm; and Line (b) was treated with an Excimer UV source which provided UV wavelengths of about 172 nm. For both treatments, tensile stresses increased from about 800 MPa (for the as-deposited silicon nitride) to 1.8 and 1.4 GPa, respectively, after about 50 seconds of ultraviolet exposure material. The sample of FIG. 17E was deposited using 60 sccm flow rate of silane; 300 sccm flow rate of ammonia; 10,000 sccm nitrogen; electrode power of 150 watt; pressure of 6 Torr; and 11 mm spacing. The deposited material was treated with a Fusion H source. As before, the as-deposited silicon nitride material increased in tensile stress after approximately 50 seconds of treatment from about 700 MPa to 1.6 GPa.

It was also determined that the effect of the ultraviolet exposure could be enhanced by providing an optimal range of the diluent gas content to the process gas during the deposition process. This was done to reduce the number of nitrogen-hydrogen bonds in the deposited material, which are typically more difficult to remove by the ultraviolet treatment than silicon-hydrogen bonds. Thus, the deposited silicon nitride materials, which were subsequently subjected to ultraviolet exposure, the deposited at slightly different process conditions in which the diluent gas flow was reduced to the range of from about 5000 to about 15,000 sccm and more preferably about 10,000 sccm. The silane and ammonium volumetric flow ratios and flow rates were from about 1:2 to about 1:15, and more preferably about 1:10.

Electron Beam Exposure

The as-deposited silicon nitride material can also be treated by exposure to an electron beam in the exposure apparatus 200. An exposure source 204 that is a suitable source of electron beams can comprise either a line electron source that is scanned across the deposited material for example, or a large area electron beam exposure system, such as that described in U.S. Pat. No. 5,003,178 to Livesay, which is incorporated herein by reference in its entirety. The electron beam exposure is conducted by flood exposing our scanning substantially the entire area of the deposited material with electron beam radiation. The deposited material is preferably subjected to an electron beam radiation from a uniform large-area electron beam source under electron beam conditions that are sufficient to cover the full width and thickness of the material. Preferably the exposure is conducted with an electron beam which covers an area of from about 4 square inches to about 256 square inches.

The electron beam exposure conditions depend upon the total dosage applied, the electron beam energy applied to the deposited material, and the electron beam current density. In one version, the electron beam exposure is done in a vacuum of from about 10⁻⁵ to about 10⁻² Torr, and with a substrate temperature in the range of from about 100° C. to about 400° C. The exposure energy may be in the range of from about 0.1 to about 100 keV, and the electron beam current is typically from about 1 to about 100 mA. The electron beam dose falls into the range of from about 1 to about 100,000 μC/cm². The dose and energy selected will be proportional to the thickness of the deposited material to be processed. Generally, the electron beam exposure will be from about 0.5 minute to about 10 minutes. The dosage energy of electrons provided by the electron beam can also be selected to obtain predetermined stress value in the deposited silicon nitride material.

FIG. 18 is a graph showing the tensile stress values for materials deposited under different process conditions labeled A to F, and before and after treatment with an electron beam. In this example, the process conditions A to F used to deposit the stressed material were as follows:
A: LPCVD BTBAS/NH3/N2/650 C/300 mTorr;
B: 25 sccm SiH4/50 sccm NH3/20000 sccm N2/480 mils/430 C/6 T/45WHF;
C: 25 sccm SiH4/50 sccm NH3/20000 sccm N2/480 mils/200 C/6 T/45WHF;
D: 25 sccm SiH4/50 sccm NH3/20000 sccm N2/480 mils/200 C/6 T/45WHF followed by annealing at 400 C for 10 min with 18000 sccm N2/4.2 Torr
E: 50 sccm SiH4/50 sccm NH3/20000 sccm N2/480 mils/200 C/6 T/45WHF; and
F: 50 sccm SiH4/50 sccm NH3/20000 sccm N2/480 mils/200 C/6 T/45WHF followed by annealing at 400 C for 10 min with 18000 sccm N2/4.2 Torr. The electron beam treatment was carried out at 4 KV, with a current of 6 mA, at a substrate temperature of 400° C., to provide a dosage of 200 to 1500.

Generally, the tensile stress values increased with electron beam treatment. The increase was more pronounced for materials having lower pre-treatment tensile stress values. For example, for the deposited material labeled C, the tensile stress value increased from around 200 MPa before treatment to about 800 MPa after electron beam treatment. The deposited material labeled E increased in tensile stress from about 200 MPa before treatment to over about 1200 MPa after electron beam treatment. Thus, electron beam treatment can be used to increase the tensile stress value of deposited materials.

In one version, the chemical vapor deposition of the deposited material and electron beam surface treatment is conducted in a cluster tool having a chemical vapor deposition chamber, an electron beam irradiation chamber, and a robot for transferring the substrate from the chemical vapor deposition chamber to the electron beam irradiation chamber. The treatment in the chemical vapor deposition chamber, electron beam irradiation chamber and the transferring from the chemical vapor deposition chamber to the electron beam irradiation chamber are conducted while maintaining vacuum conditions.

II Compressive Stressed Materials

Deposition process and treatment conditions can also be tailored to deposit a compressive stressed material on the substrate or to treat a material during or after deposition to increase its compressive stress value. Without being limited by the explanation, it has been discovered that a silicon nitride stressed material having higher compressive stress values can be obtained by increasing the RF bombardment to achieve higher film density by having more Si—N bonds in the deposited material and reducing the density of Si—H and N—H bonds. Higher deposition temperatures and RF power improved the compressive stress levels of the deposited film. In addition, higher compressive stresses-levels were obtained in the deposited material at higher kinetic energy levels of plasma species. It is believed that bombardment of energetic plasma species, such as plasma ions and neutrals, generates compressive stresses in the deposited material because film density increases.

As with the deposition of tensile-stressed materials, the process gas used to deposit compressive stressed silicon nitride also includes the silicon-containing and nitrogen-containing gases previously described. Also the general deposition process conditions, such as radio frequency type and power levels, gas flow rates and pressure, substrate temperature and other such process are about the same as those used for the deposition of tensile stressed materials, unless otherwise specified.

To deposit a compressive stressed silicon nitride material, the process gas introduced into the chamber comprises a first component that includes a silicon-containing gas and a second component that includes a nitrogen-containing gas. The silicon-containing gas can be, for example, silane, disilane, trimethylsilyl (TMS), tris(dimethylamino)silane (TDMAS), bis(tertiary-butylamino)silane (BTBAS), dichlorosilane (DCS), and combinations thereof. For example, a suitable silane flow rate is from about 10 to about 200 sccm. The nitrogen-containing gas can be, for example, ammonia, nitrogen, and combinations thereof. A suitable ammonia flow rate is from about 50 to about 600 sccm. The process gas can also include a diluent gas that is provided in a much larger volume than the reactive gas components. The diluent gas can also serve both as a diluent and at least partially as a reactant nitrogen-containing gas, for example, nitrogen in a flow rate of from about 500 to about 20,000 sccm. Other gases that can be included can be inert gases, such as for example, helium or argon, in a flow rate of from about 100 to about 5,000 sccm. The process gas may also contain additional gases such as an oxygen-containing gas, for example, oxygen, when depositing silicon oxy-nitride materials. Unless otherwise specified, in these processes, the electrode power level is typically maintained at from about 100 to about 400 Watts; electrode spacing is from about 5 mm (200 mils) to about 12 mm (600 mils); process gas pressure is from about 1 Torr to about 4 Torr; and substrate temperature is from about 300 to about 600° C.

Argon, Helium Addition

One preferred gas composition to deposit compressive stressed materials, comprises a first component comprising a silicon-containing gas and a nitrogen-containing gas, and a second component comprising an inert gas such as argon or helium. Higher compressive stress values were obtained in the deposited material with higher volumetric flow ratios of second component to first component. It is believed that this occurs because the inert gas component serves to increase plasma density, and thus, the ion bombardment and reduce the overall H content of the film. In one preferred composition, the process gas comprises (i) a first component comprising a silicon-containing gas such as silane, and a nitrogen-containing gas such as ammonia and nitrogen, and (ii) a second component comprising either argon or helium. The ratio of the second component to the first component is at least about 1:1, and more preferably less than about 1:4. Generally, the pressure used for the process gas was from about 6 to 10 Torr. The temperature of the substrate was maintained between about 400 and 550° C. Electrode spacing was maintained from about 7.6 mm to about 15.2 mm (300 to 600 mil).

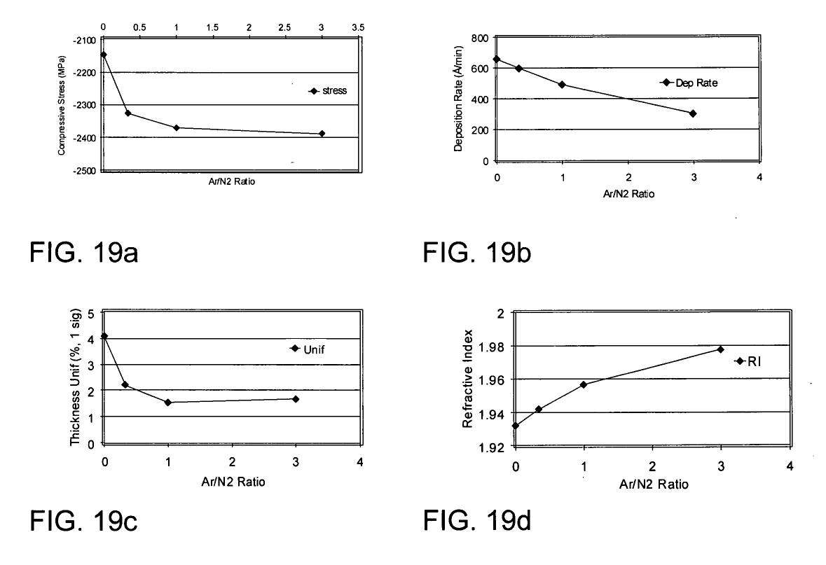

FIGS. 19A to 19D show the effect of argon to nitrogen flow rate ratio on the compressive stress value, deposition rate, thickness uniformity and refractive index, respectively, of the deposited material. In this example, the process conditions used to deposit the stressed material were as listed in Table III, Cond. 4. Generally, increasing the ratio of Ar to N₂ results in higher compressive stress values (as evidenced by the higher absolute stress value), decreases deposition rate and the thickness of the deposited material, and increases refractive index. The decline in the compressive stress and thickness uniformity levels begin to level off at a ratio of argon to nitrogen of about 1. With increasing argon to nitrogen ratios from 1:1 to 3:1, the compressive stress value only slightly increased from about −2.36 to about −2.38 GPa. Thus, it was determined that optimal compressive stress values were obtained in the deposited material with a flow ratio of argon to nitrogen of at least about 1:1, and more preferably from about 1:1 to about 3:1. Typically, the flow rate of argon was from about 1000 to about 10,000 sccm; and the flow rate of nitrogen was from about 1,000 to about 20,000 sccm. It is believed that helium can also be substituted for argon in the same volumetric flow ratios to give about the same results.

Compressive: SiH₄, N₂, NH₃ and Ar, with Low RF Voltage

In this embodiment, the process gas used included (i) a first component comprising silicon-containing gas, such as silane, (ii) a second component comprising nitrogen and ammonia, and (iii) a third component comprising argon. When silane and ammonia were used, a high volumetric flow ratio of silane to ammonia was found to provide higher compressive stress values in the deposited material, as shown in Table III below. It was found that high volumetric flow ratios of SiH₄/NH₃ also provided better plasma stability which enhance deposition uniformity and also contributed to higher stress levels. Generally, the flow ratio of silane to ammonia was at least about 0.2, and more preferably from about 0.25 to about 3. The flow rate of silane was from typically from about 10 to about 100 sccm; and the flow rate of ammonia was from about 20 to about 300 sccm. The flow rate of nitrogen was 1000 and argon was 3000 sccm.

The compressive stresses were further enhanced in the deposited material by applying a low RF voltage to the electrodes to generate a plasma of the process gas, the low RF voltage having frequencies of less than about 1 MHz, and more preferably from about 100 KHz to 1 MHz, or even about 300 KHz. The low RF voltage generated additional compressive stresses in the deposited material to increase ion bombardment to the substrate and achieve high density film. In this embodiment, a suitable power level of the low radio frequency voltage was from about 50 to about 300 Watts.

Combination of Low RF and High RF

Increased bombardment of deposited material with energetic plasma species during or after deposition can also be achieved by selecting the frequency range and power level of the high frequency voltage applied across the chamber electrodes. It was determined that higher compressive stress values were obtained in the deposited material using a combination of the low radio frequency power and high radio frequency power. In one example, the optimal low radio frequency to obtain high compressive stress values was found to be less than about 1 MHz, and more preferably from about 100 KHz to 1 MHz, and even about 300 KHz. The optimal high radio frequency levels used in combination with the aforementioned low radio frequency levels, was from about 10 MHz to about 27 MHz, and more preferably about 13.5 MHz.

Application of a combination of both low and high radio frequency power levels was found to generate the highest compressive stress values. Further enhanced compressive stress values were obtained at higher power levels of both the low and high RF voltages. For low RF voltages, the power levels of should be at least about 50, and more preferably from about 100 to about 400 Watts. Suitable power levels for the high RF voltages were at least about 100, and more preferably from about 200 to about 500 Watts.

Small Spacing Gap and Low Gas Pressure

A compressive stressed material can be formed on the substrate 32 by setting a spacing distance dₛ between the first electrode 105 and second electrode 109 that is sufficiently low to significantly increase the kinetic energy of the plasma species bombarding the substrate 32. For example, when the first electrode 105 is the substrate support 104 and the second electrode 109 is the gas distributor 108, the spacing between the two electrodes 105, 109 is set by adjusting the height of the substrate support 104 in the chamber. Preferably, the spacing distance dₛ of the electrodes is less than about 25 mm, and more preferably at least about 11 mm. In addition to the electrode spacing, the gas pressure of the process gas in the chamber is also set to a higher level to further increase plasma ion bombardment energy in the chamber 80. It is believed that the low spacing distance and higher gas pressures increase the ion bombardment energy of the plasma species in the chamber, thereby depositing materials that have compressive stresses. Suitable process gas pressures are at least about 5, and more preferably from about 1.5 to about 3.5 Torr.

Table III illustrates sets of process parameters used to deposit compressive stressed materials. Process gas composition, flow rates and other variables are the same as previous examples. The parameters suitable for various embodiments of silicon nitride material deposition processes, including suitable temperatures, SiH₄, NH₃, N₂ and Ar flow rates, high radio frequency power levels, low radio frequency power levels, electrode spacing and process gas pressure. The resulting deposition rates, uniformity, refractive index, stress values and plasma stabilities are also listed.

TABLE III
Process Parameter Sets Used for High Compressive Stresses Levels

| Process | | | | |
|---|---|---|---|---|
| Conditions | 1 | 2 | 3 | 4 |
| Temperature | 400° C. | 400° C. | 400° C. | 400° C. |
| SiH₄ | 120 sccm | 60 sccm | 60 sccm | 60 sccm |
| NH₃ | 120 sccm | 30 sccm | 120 sccm | 130 sccm |
| N₂ | 5000 sccm | 4000 sccm | 1000 sccm | 1000 sccm |
| Ar | 0 sccm | 0 sccm | 3000 sccm | 3000 sccm |
| HF RF Power | 0 W | 100 W | 175 W | 200 W |
| LF RF Power | 150 W | 150 W | 150 W | 150 W |
| Spacing | 8 mm (325 mils) | 8 mm | 8 mm | 11 mm (425 mils) |
| Pressure | 1.4 T | 1.2 T | 2 T | 2 T |
| Dep. Rate | 730 Å/min | 686 Å/min | 780 Å/min | 860 Å/min |
| Uniformity | 6.0%, 1 sigma | 3.3%, 1 sigma | 2.9%, 1 sigma | 1.5%, isigma |
| RI | 1.95 | 1.95 | 1.94 | 1.94 |
| Stress | −2.0 GPa | −2.2 GPa | −2.4 GPa | −2.3 GPa |
| Plasma Stability | Stable | Unstable | Unstable | Stable |

III. Fabrication of MOSFET with Stressed Material

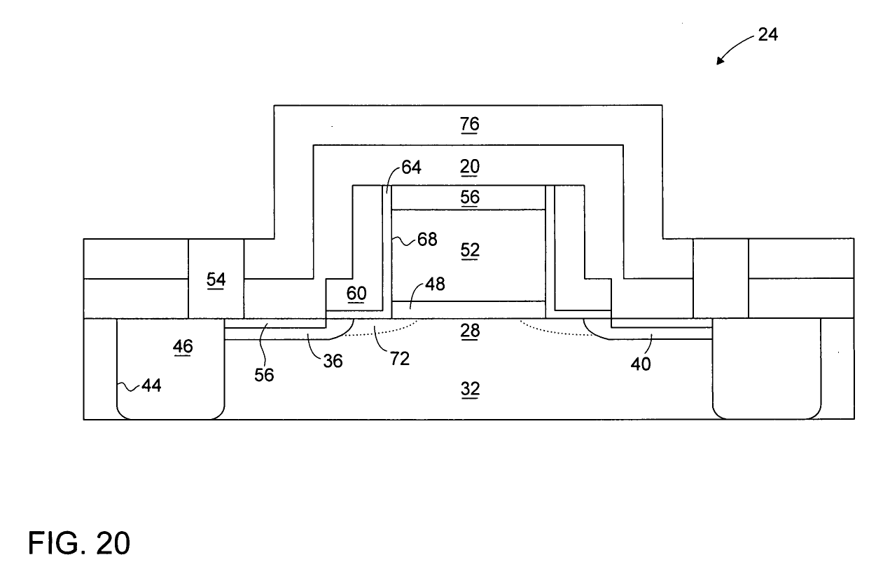

In one exemplary application, the tensile or compressive stressed silicon nitride material is formed on a substrate 32 in the fabrication of a MOSFET structure 392—which is illustrated in the simplified cross-sectional diagram of FIG. 20. The relatively high internal stress of the deposited and treated silicon nitride material 20 induces a strain in a channel region 28 of the transistor 24. The induced strain improves carrier mobility in the channel region 28 which improves transistor performance, such as for example, by increasing the saturation current of the transistor 24. The silicon nitride material 20 can also have other uses within the MOSFET 24, for example, as an etch stop material. The highly stressed silicon nitride material 20 is also useful in other structures, such as other transistors including without limitation, bipolar junction transistors, capacitors, sensors, and actuators. The substrate can be a silicon wafer or can be made from other materials such as germanium, silicon germanium, gallium arsenide and combinations thereof. The substrate 32 can also be a dielectric, such as glass, which is used in the fabrication of displays.

The transistor 24 illustrated in FIG. 20 is a negative channel, or n-channel, MOSFET (NMOS) having source and drain regions 36, 40 that are formed by doping the substrate 32 with a Group VA element to form an n-type semiconductor. In the NMOS transistor, the substrate 32 outside of the source and drain regions 36, 40 is typically doped with a Group IIIA element to form a p-type semiconductor. For the NMOS channel regions, the overlying stressed silicon nitride material is fabricated to have a tensile stress.

In another version, the MOSFET transistor 24 comprises a positive channel or p-channel MOSFET (PMOS), (not shown) which has source and drain regions that are formed by doping the substrate with a Group IIIA element to form a p-type semiconductor. In a PMOS transistor, the transistor 24 may comprise a substrate 32 comprising an n-type semiconductor or may have a well region (not shown) comprising an n-type semiconductor formed on a substrate 32 comprising a p-type semiconductor. The PMOS channel regions are covered with a compressive stressed silicon nitride material.

In the version shown, the transistor 24 comprises a trench 44 to provide isolation between transistors 24 or groups of transistors 24 on the substrate 32, a technique known as shallow trench isolation. The trench 44 is typically formed prior to the source and drain regions 36, 40 by an etch process. A trench side wall liner material (not shown) may be formed in the trench 44 by, for example, a rapid thermal oxidation in an oxide/oxinitride atmosphere, which may also round sharp corners on the trench 44 (and elsewhere). In one version, the trench 44 may be filled with material 46 having a tensile stress, which can also be used to provide a tensile stress to the channel region 28. The deposition of the trench material 46 which may include the use of a High Aspect Ratio Process (HARP), which may include using an O₃/tetraethoxy silane (TEOS) based sub-atmospheric chemical vapor deposition (SACVD) process. Excess trench material 46 may be removed by, for example, chemical mechanical polishing.

The transistor comprises a gate oxide material 48 and a gate electrode 52 on top of the channel region 28 between the source and drain regions 36, 40. In the version shown, the transistor 24 also comprises silicide materials 56 on top of the source and drain regions 36, 40 as well as the gate electrode 52. The silicide materials 56 are highly conductive compared to the underlying source and drain regions 36, 40 and gate electrode 52, and facilitate the transfer of electric signals to and from the transistor 24 through metal contacts 54. Depending on the materials and formation processes used, the silicide materials 56 may also comprise a tensile stress and produce tensile strain in the channel region 28. The transistor shown also comprises spacers 60 and oxide-pad materials 64 which may be located on opposite sidewalls 68 of the gate electrode 52 to keep the silicide materials 56 separated during a silicidation process to form the silicide materials 56. During silicidation, a continuous metal material (not shown) is deposited over the oxide-containing source and drain regions 36, 40 and gate electrode 52, as well as the nitride containing spacers 60. The metal reacts with the underlying silicon in the source and drain regions 36, 40 and gate electrode 52 to form metal-silicon alloy silicide materials, but are less reactive with the nitride materials in spacers 60. Thus, the spacers 60 allow the overlying, unreacted metal to be etched away while not affecting the metal alloy in silicide materials 56.

The length of the channel region 28 is shorter than the length of the gate oxide material 48. The length of the channel region 28 measured between the edges of the source region 36 and the drain region 40 may be about 90 nm or less, for example, from about 90 nm to about 10 nm. As the length of channel region 28 gets smaller, implants 72, also known as halos, may be counter-doped into the channel region 28 to prevent charge carriers from uncontrollably hopping from the source region 36 to the drain region 40 and vice versa.

In the version shown in FIG. 20, the silicon nitride material 20 is formed above the silicide materials 56. The silicon nitride material 20 typically acts as a contact-etch stop material as well as providing strain to the channel region 28. The silicon nitride material 20 is capable of being deposited to have a stress values ranging from compressive to tensile stresses. The selection of the stress in the silicon nitride material 20 selects the type of strain provided to the channel region 28 of the transistor 24.

Following the formation of the silicon nitride material 20, a dielectric material 76, also referred to as a pre-metal dielectric material, may be deposited on the silicon nitride material 20. The dielectric material 76 may be, for example, borophosphosilicate glass, phosphosilicate glass, borosilicate glass, and phosphosilicate glass, among other materials. The dielectric material 76 may be formed using HARP that includes O₃/TEOS in conjunction with SACVD. The dielectric material 76 may also comprise a tensile stress which produces a tensile strain in the channel region 28.

Although exemplary embodiments of the present invention are shown and described, those of ordinary skill in the art may devise other embodiments which incorporate the present invention, and which are also within the scope of the present invention. For example, other radiation treatments, such as infrared radiation or selected wavelengths of visible light may also be used to treat the deposited film. Also, a combination of different radiation exposures can also be used. Furthermore, the terms below, above, bottom, top, up, down, first and second and other relative or positional terms are shown with respect to the exemplary embodiments in the FIGS. and are interchangeable. Therefore, the appended claims should not be limited to the descriptions of the preferred versions, materials, or spatial arrangements described herein to illustrate the invention.

What is claimed is:

1. A method of forming a stressed material on a substrate, the method comprising:
(a) depositing a material on the substrate by:
(i) placing the substrate in a first process zone;
(ii) introducing into the process zone, a process gas comprising silicon-containing gas and nitrogen-containing gas;
(iii) generating a plasma of the process gas; and
(iv) exhausting the process gas from the process zone; and
(b) exposing the deposited material to ultraviolet radiation to increase the stress value of the deposited material.

2. A method according to claim 1 wherein (b) comprises exposing the deposited material to broadband ultraviolet radiation.

3. A method according to claim 1 wherein (b) comprises selecting the wavelength and intensity of the ultraviolet radiation to obtain a predetermined range of tensile stress values in the deposited material.

4. A method according to claim 1 wherein the process gas further comprises a diluent gas.

5. A method according to claim 1 wherein the process gas comprises SiH₄, NH₃ and N₂, whereby a stressed material comprising silicon nitride is deposited.

6. A method of increasing the stress value of a material deposited on a substrate, the method comprising:
(a) exposing the material to ultraviolet radiation.

7. A method of forming a stressed material on a substrate, the method comprising:
(a) depositing a material on the substrate by:
(i) placing the substrate in a process zone;
(ii) introducing into the process zone, a process gas comprising silicon-containing gas and nitrogen-containing gas;
(iii) generating a plasma of the process gas; and
(iv) exhausting the process gas from the process zone; and
(b) exposing the deposited material to an electron beam to increase the stress value of the deposited material.

8. A method according to claim 7 comprising setting at least one of the energy of electrons in the electron beam, the dosage energy delivered by the electron beam, and the current of the electron beam, to increase the stress value of the deposited material.

9. A method according to claim 7 wherein (b) comprises selecting the dosage energy of electrons provided by the electron beam to obtain a predetermined range of tensile stress values in the deposited material.

10. A method according to claim 7 wherein (b) comprises exposing the deposited material to an electron beam that provides an exposure energy of from about 0.1 to about 100 keV.

11. A method according to claim 7 wherein (b) comprises exposing the deposited material to an electron beam that provides an electron beam current of from about 1 to about 100 mA.

12. A method according to claim 7 wherein (b) comprises exposing the deposited silicon nitride material to an electron beam dose of from about 1 to about 100,000 μC/cm².

13. A method according to claim 7 wherein (b) comprises exposing the deposited material to an electron beam in a vacuum of from about 10⁻⁵ torr to about 10⁻² Torr.

14. A method according to claim 7 wherein (b) comprises maintaining the substrate at a temperature of from about 100° C. to about 400° C.

15. A method according to claim 7 wherein (b) comprises exposing the deposited material to an electron beam for about 0.5 to about 10 minutes.

16. A method according to claim 7 wherein in (a) the process gas further comprises a diluent gas.

17. A method according to claim 7 wherein the process gas comprises SiH₄, NH₃ and N₂, whereby a stressed material comprising silicon nitride is deposited.

18. A method of increasing the stress of a material deposited on a substrate, the method comprising:
(a) exposing the material to an electron beam to increase a tensile stress value of the material.

19. A method of depositing a stressed material on a substrate, the method comprising:
(a) placing the substrate in a process zone;
(b) in a first process cycle, maintaining a plasma of a process gas flowed into the process zone, the process gas comprising a first component comprising silicon-containing gas and nitrogen-containing gas that is not nitrogen, and a second component comprising nitrogen;
(c) in a second process cycle, stopping the flow of the first component of the process gas, while maintaining the plasma of the second component comprising nitrogen; and
(d) exhausting the process gas from the process zone.

20. A method according to claim 19 wherein (b) and (c) are repeated for a plurality of process cycles.

21. A method according to claim 19 wherein the silicon-containing gas comprises silane and the nitrogen-containing gas comprises ammonia.

22. A method according to claim 19 wherein the process gas comprises SiH₄, NH₃ and N₂, whereby a tensile stressed material comprising silicon nitride is deposited.

23. A method of depositing a stressed material on a substrate in a process zone that is bounded by electrodes of a process chamber, the method comprising:
(a) placing the substrate in the process zone;
(b) introducing into the process zone, a process gas comprising silicon-containing gas and nitrogen-containing gas;
(c) generating a pulsed plasma of the process gas by applying voltage pulses across the electrodes bounding the process zone, the voltage pulses each having a duty cycle, and the voltage pulses delivering a high radio frequency voltage to the electrodes at a power level of from about 100 to about 500 Watts; and
(d) exhausting the process gas from the process zone.

24. A method according to claim 23 wherein the duty cycle of the voltage pulses is from about 10 to about 50%.

25. A method according to claim 23 wherein the voltage pulses are rectangular pulses.

26. A method according to claim 23 comprising selecting the duty cycle of the voltage pulses to select the stress value of the deposited stressed material.

27. A method according to claim 23 wherein the silicon-containing gas comprises SiH₄ and the nitrogen-containing gas comprises NH₃ and whereby a tensile stressed material comprising silicon nitride is deposited.

28. A method of depositing a stressed material on a substrate, the method comprising:
(a) placing the substrate in a process zone;
(b) introducing into the process zone, a process gas comprising a first component comprising silane and ammonia, and a second component comprising nitrogen, the volumetric flow ratio of the first component to the second component being at least about 1:10;
(c) generating a plasma of the process gas; and
(d) exhausting the process gas from the process zone.

29. A method according to claim 28 wherein the substrate comprises a nickel silicide material, and the method comprises maintaining the substrate at temperatures from about 450° C. to about 500° C.

30. A method according to claim 28 comprising providing nitrogen at a flow rate per unit chamber volume of from about 0.8 to about 1.

31. A method according to claim 28 comprising providing nitrogen at a volumetric flow rate of from about 20,000 to about 25,000 sccm.

32. A method according to claim 28 wherein the process gas consists essentially of SiH₄, NH₃ and N₂, whereby a tensile stressed material comprising silicon nitride is deposited.

33. A method of depositing a stressed material on a substrate, the method comprising:
(a) placing the substrate in a process zone;
(b) introducing into the process zone, a process gas comprising silane and ammonia in a volumetric flow ratio of from about 1:1 to about 1:3, and that is sufficiently low to deposit a tensile stressed material having a tensile stress value of at least about 500 MPa;
(c) generating a plasma of the process gas; and
(d) exhausting the process gas from the process zone.

34. A method according to claim 33 wherein volumetric flow ratio of silane to ammonia is about 1:2.

35. A method according to claim 33 wherein the process gas comprises SiH₄, NH₃ and N₂, whereby a tensile stressed material comprising silicon nitride is deposited.

36. A method of depositing stressed material on a substrate, the method comprising:
(a) placing the substrate in a process zone, and maintaining the substrate at temperatures from about 350° C. to about 500° C.;
(b) introducing into the process zone, a process gas comprising silicon-containing gas and nitrogen-containing gas;
(c) forming a plasma of a process gas in the process zone; and
(d) exhausting the process gas from the process zone.

37. A method according to claim 36 comprising placing in the process zone, a substrate having a nickel silicide layer thereon, whereby the stressed silicon nitride material is formed on the nickel silicide layer.

38. A method according to claim 36 wherein the process gas comprises SiH₄, NH₃ and N₂, whereby a tensile stressed material comprising silicon nitride is deposited.

39. A method of depositing a stressed material on a substrate in a process zone bounded by electrodes of a process chamber, the method comprising:
(a) placing the substrate in a process zone;
(b) introducing a process gas into the process zone, the process gas comprising silicon-containing gas and nitrogen-containing gas;
(c) generating a plasma of the process gas by applying across the electrodes about the process zone, a high radio frequency voltage having a frequency in the range of from about 3 MHz to about 60 MHz, and at a power level of less than about 200 Watts; and
(d) exhausting process gas from the process zone.

40. A method according to claim 39 wherein the high radio frequency voltage is provided at a power level of from about 10 Watts to about 100 Watts.

41. A method according to claim 39 wherein the silicon-containing gas comprises SiH₄ and the nitrogen-containing gas comprises NH₃ and N₂, whereby a stressed material comprising tensile stressed silicon nitride is deposited.

42. A method of depositing a stressed material on a substrate in a process zone bounded by electrodes comprising a substrate support and a chamber wall, the method comprising:
(a) placing a substrate on the substrate support:
(b) maintaining the substrate support at an electrically floating potential relative to the chamber wall;
(c) introducing into the process zone, a process gas comprising silicon-containing gas and nitrogen-containing gas;
(d) generating a plasma of the process gas by applying a radio frequency voltage across the electrodes; and
(e) exhausting the process gas from the process zone.

43. A method according to claim 42 comprising maintaining a radio frequency voltage having a frequency of from about 350 kHz to about 20 MHz.

44. A method according to claim 42 wherein the silicon-containing gas comprises SiH₄ and the nitrogen-containing gas comprises NH₃ and N₂, whereby a stressed material comprising tensile stressed silicon nitride is deposited.

45. A method of depositing a stressed material on a substrate in a process zone bounded by electrodes comprising a substrate support and a gas distributor, the method comprising:
(a) placing the substrate on the substrate support;
(b) introducing a process gas through the gas distributor and into the process zone, the process gas comprising silicon-containing gas and nitrogen-containing gas;
(c) applying a negative DC bias voltage to the gas distributor;
(d) generating a plasma of the process gas; and
(e) exhausting the process gas from the process zone.

46. A method according to claim 45 comprising applying a negative DC bias voltage that is from about 25 to about 100 volts.

47. A method according to claim 45 wherein the substrate support is spaced apart from the gas distributor by a separation distance dₛ of from about 5 to about 15 mm.

48. A method according to claim 45 wherein the silicon-containing gas comprises SiH₄ and the nitrogen-containing gas comprises NH₃ and N₂, whereby a stressed material comprising tensile stressed silicon nitride is deposited.

49. A method of depositing a stressed material on a substrate in a process zone bounded by electrodes comprising a substrate support and a gas distributor, the method comprising:
(a) placing the substrate on the substrate support;
(b) applying a positive DC bias voltage to the substrate support;
(c) introducing a process gas through the gas distributor and into the process zone, the process gas comprising silicon-containing gas and nitrogen-containing gas;
(d) generating a plasma of the process gas; and
(e) exhausting the process gas from the process zone.

50. A method according to claim 49 comprising applying a positive DC bias voltage that is at least about 25 volts.

51. A method according to claim 49 comprising applying a positive DC bias voltage that is from about 50 to about 100 volts.

52. A method according to claim 54 wherein the substrate support is spaced apart from the gas distributor by a separation distance dₛ of from about 5 to about 15 mm.

53. A method according to claim 54 wherein the silicon-containing gas comprises SiH₄ and the nitrogen-containing gas comprises NH₃ and N₂, whereby a stressed material comprising tensile stressed silicon nitride is deposited.

54. A method of depositing a stressed material on a substrate, the method comprising:
(a) in a deposition process cycle, depositing a stressed material on the substrate by:
(i) placing the substrate in a process zone;
(ii) introducing a process gas into the process zone, the process gas comprising silicon-containing gas and nitrogen-containing gas;
(iii) generating a plasma of the process gas; and
(iv) exhausting the process gas from the process zone; and
(b) in an annealing process cycle, heating the deposited stressed material on the substrate to a temperature of at least about 450° C.

55. A method according to claim 54 wherein (a) comprises heating the substrate to a temperature of less than about 420° C.

56. A method according to claim 54 wherein (b) comprises maintaining a gas comprising nitrogen about the substrate during annealing.

57. A method according to claim 54 wherein the silicon-containing gas comprises SiH₄ and the nitrogen-containing gas comprises NH₃ and N₂, whereby a stressed material comprising tensile stressed silicon nitride is deposited.

58. A method of depositing a stressed material on a substrate, the method comprising:
(a) placing the substrate in a process zone;
(b) introducing a process gas into the process zone, the process gas comprising: (i) a first component introduced at a first flow rate, the first component comprising silicon-containing gas and nitrogen-containing gas, and (ii) a second component introduced at a second flow rate, the second component comprising helium or argon, and wherein the volumetric flow ratio of the second component to first component is at least about 1:1;
(c) generating a plasma of the process gas; and
(d) exhausting the process gas from the chamber.

59. A method according to claim 58 wherein the volumetric flow ratio is less than about 1:4.

60. A method according to claim 58 wherein the nitrogen-containing gas comprises nitrogen and the second component consists essentially of helium, and volumetric flow ratio is from about 1:1 to about 1:3.

61. A method according to claim 58 wherein the nitrogen-containing gas comprises nitrogen and the second component consists essentially of argon, and volumetric flow ratio is from about 1:1 to about 1:3.

62. A method according to claim 58 wherein the silicon-containing gas comprises SiH₄ and the nitrogen-containing gas comprises NH₃ and N₂, whereby a stressed material comprising tensile stressed silicon nitride is deposited.

63. A method of depositing a stressed material on a substrate in a process zone that is bounded by electrodes in a process chamber, the method comprising:
(a) placing the substrate in the process zone;
(b) introducing a process gas into the process zone, the process gas comprising: (i) a first component comprising silicon-containing gas, (ii) a second component comprising nitrogen and ammonia, and (iii) a third component comprising argon;
(c) applying a low RF voltage to the electrodes to generate a plasma of the process gas, the low RF voltage having a frequency that is less than about 1 MHz; and
(d) exhausting the process gas from the chamber.

64. A method according to claim 63 wherein the low RF voltage is from about 100 KHz to about 1 MHz.

65. A method according to claim 63 wherein the low RF voltage is about 300 KHz.

66. A method according to claim 63 wherein the silicon-containing gas comprises silane, and wherein the ratio of silane to ammonia is at least about 0.2.

67. A method according to claim 66 wherein the ratio of silane to ammonia is from about 0.25 to about 3.

68. A method of depositing a stressed material on a substrate in a process zone bounded by electrodes in a chamber, the method comprising:
(a) placing the substrate in the process zone;
(b) introducing into the process zone, a process gas comprising silicon-containing gas and nitrogen-containing gas;
(c) generating a plasma of the process gas by applying to the electrodes (i) a low radio frequency voltage at a frequency less than about 1 MHz and a power level of at least about 50 watts, and (ii) a high radio frequency voltage at a frequency of at least about 10 MHz and a power level of at least about 100 watts; and
(d) exhausting the process gas from the chamber.

69. A method according to claim 68 wherein the low radio frequency voltage is at a frequency of at least about 100 KHz.

70. A method according to claim 68 wherein low radio frequency voltage is provided at a power level of less than about 400 watts.

71. A method according to claim 68 wherein the high radio frequency voltage is at a frequency of less than about 27 MHz.

72. A method according to claim 68 wherein high radio frequency voltage is provided at a power level of less than about 500 watts.

73. A method according to claim 68 wherein the silicon-containing gas comprises SiH₄ and the nitrogen-containing gas comprises NH₃ and N₂, whereby a stressed material comprising tensile stressed silicon nitride is deposited.

74. A method of depositing a stressed material on a substrate in a process zone bounded by electrodes in a process chamber, the method comprising:
(a) placing the substrate in the process zone;
(b) introducing into the process zone, a process gas comprising silicon-containing gas and nitrogen-containing gas;
(c) generating a plasma of the process gas by (i) setting a spacing distance dₛ of the electrodes that is less than about 25 mm, and (ii) applying a radio frequency voltage to the electrodes; and
(d) exhausting the process gas from the chamber to set a pressure of at least about 5 Torr,
whereby a compressive stressed layer is deposited on the substrate.

75. A method according to claim 74 wherein the spacing distance dₛ of the electrodes is at least about 11 mm.

76. A method according to claim 74 wherein the pressure of the process gas is from about 1.5 to about 3.5 Torr.

77. A method according to claim 74 wherein the silicon-containing gas comprises SiH₄ and the nitrogen-containing gas comprises NH₃ and N₂, whereby a stressed material comprising tensile stressed silicon nitride is deposited.
